(19) United States
(12) Patent Application Publication
(10) Pub. No.: US 2024/0389330 A1
(43) Pub. Date: Nov. 21, 2024

(54) SEMICONDUCTOR DEVICES AND DATA STORAGE SYSTEMS INCLUDING THE SAME

(71) Applicant: SAMSUNG ELECTRONICS CO., LTD., Suwon-si (KR)

(72) Inventors: Yongseok KWON, Suwon-si (KR); Jaeduk YU, Suwon-si (KR); Bongsoon LIM, Suwon-si (KR)

(73) Assignee: SAMSUNG ELECTRONICS CO., LTD., Suwon-si (KR)

(21) Appl. No.: 18/444,165

(22) Filed: Feb. 16, 2024

(30) Foreign Application Priority Data
May 19, 2023 (KR) 10-2023-0064881

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

A semiconductor device is provided. The semiconductor device includes: a first semiconductor structure including a substrate, circuits on the substrate, and a lower interconnection structure electrically connected to the circuits; and a second semiconductor structure including: a plate layer on the first semiconductor structure; gate electrodes and interlayer insulating layers alternately stacked on the plate layer in a first direction that is perpendicular to an upper surface of the plate layer; channel structures passing through the gate electrodes and extending in the first direction; and an upper capacitor structure including an upper gate electrode on the interlayer insulating layers and an upper contact structure extending through the upper gate electrode in the first direction.

### CROSS-REFERENCE TO RELATED APPLICATION(S)

This application claims priority to Korean Patent Application No. 10-2023-0064881, filed on May 19, 2023, in the Korean Intellectual Property Office, the disclosure of which is hereby incorporated by reference in its entirety.

### BACKGROUND

The present disclosure relates to a semiconductor device and a data storage system including the same.

In a data storage system, a semiconductor device for storing high-capacity data may be required. Accordingly, methods for increasing data storage capacity of semiconductor devices are being researched. For example, as a method for increasing data storage capacity of a semiconductor device, a semiconductor device including memory cells arranged three-dimensionally, instead of memory cells arranged two-dimensionally, has been proposed.

### SUMMARY

One or more example embodiments provide a semiconductor device having improved electrical characteristics and reliability.

One or more example embodiments provide a data storage system including a semiconductor device having improved electrical characteristics and reliability.

According to an aspect of an example embodiment, a semiconductor device includes: a first semiconductor structure including a substrate, circuits on the substrate, and a lower interconnection structure electrically connected to the circuits; and a second semiconductor structure including: a plate layer on the first semiconductor structure; gate electrodes and interlayer insulating layers alternately stacked on the plate layer in a first direction that is perpendicular to an upper surface of the plate layer; channel structures passing through the gate electrodes and extending in the first direction; and an upper capacitor structure including an upper gate electrode on the interlayer insulating layers and an upper contact structure extending through the upper gate electrode in the first direction. The upper contact structure includes an upper contact plug and an upper contact insulating layer between a sidewall of the upper contact structure and the upper contact plug. The upper contact structure is electrically insulated from the channel structures. A central axis of the upper contact structure is offset from central axes of the channel structures. The upper contact plug and the upper gate electrode are configured to have different potentials.

According to an aspect of an example embodiment, a semiconductor device includes: a first semiconductor structure including a substrate, circuits on the substrate, and a lower interconnection structure electrically connected to the circuits; and a second semiconductor structure on the first semiconductor structure, and including a first region, a second region adjacent to the first region, and a third region disposed outside the first region and the second region, the first region including cell blocks and dummy blocks arranged in a direction parallel to an upper surface of the substrate. The second semiconductor structure further includes: a plate layer on the first semiconductor structure; gate electrodes and interlayer insulating layers alternately stacked on the plate layer in a first direction that is perpendicular to an upper surface of the plate layer; an upper gate electrode on the interlayer insulating layers; and an upper contact structure passing through the upper gate electrode. The upper contact structure includes an upper contact plug and an upper contact insulating layer between a sidewall of the upper contact structure and the upper contact plug. The upper contact plug is configured to have a potential different from a potential of the upper gate electrode. The second semiconductor structure further includes an upper capacitor structure including the upper gate electrode, the upper contact insulating layer, and the upper contact plug in at least one region of the first to third regions.

According to an aspect of an example embodiment, a data storage system includes: a semiconductor storage device; and a controller. The semiconductor storage device includes: a first semiconductor structure including a substrate, circuits on the substrate, and a lower interconnection structure electrically connected to the circuits; and a second semiconductor structure including: a plate layer on the first semiconductor structure; gate electrodes and interlayer insulating layers alternately stacked on the plate layer in a first direction that is perpendicular to an upper surface of the plate layer; channel structures passing through the gate electrodes and extending in the first direction; and an upper capacitor structure including an upper gate electrode on the interlayer insulating layers and an upper contact structure extending through the upper gate electrode in the first direction, and including an input/output pad electrically connected to the circuits. The upper contact structure includes an upper contact plug and an upper contact insulating layer between a sidewall of the upper contact structure and the upper contact plug. The upper contact structure is electrically insulated from the channel structures. A central axis of the upper contact structure is offset from central axes of the channel structures. The upper contact plug and the upper gate electrode are configured to have different potentials. The controller is electrically connected to the semiconductor storage device through the input/output pad and is configured to control the semiconductor storage device.

### BRIEF DESCRIPTION OF DRAWINGS

The above and other aspects and features will be more apparent from the following description of example embodiments, taken in conjunction with the accompanying drawings, in which:

FIG. 1 is a schematic layout diagram illustrating a semiconductor device according to example embodiments.

FIG. 2A is a schematic plan view of a semiconductor device according to example embodiments.

FIGS. 2B, 2C and 2D are schematic horizontal cross-sectional views of a semiconductor device according to example embodiments.

FIG. 3A is a schematic cross-sectional view of a semiconductor device according to example embodiments.

FIGS. 3B, 3C, 3D and 3E are partial enlarged views of a semiconductor device according to example embodiments.

FIG. 4 is a schematic horizontal cross-sectional view of a semiconductor device according to example embodiments.

FIGS. 5A and 5B are partial enlarged views of a semiconductor device according to example embodiments.

FIGS. 6, 7A, 7B, 8A, 8B, 9A and 9B are schematic cross-sectional views of a semiconductor device according to example embodiments.

FIG. 10 is a partially enlarged view of a semiconductor device according to example embodiments.

FIG. 11 is a schematic cross-sectional view of a semiconductor device according to example embodiments.

FIGS. 12A, 12B and 12C are schematic cross-sectional views illustrating a method of manufacturing a semiconductor device according to example embodiments.

FIG. 13 is a view schematically illustrating a data storage system including a semiconductor device according to example embodiments.

FIG. 14 is a perspective view schematically illustrating an electronic system including a semiconductor device according to example embodiments.

FIG. 15 is a cross-sectional view schematically illustrating a semiconductor package according to example embodiments.

### DETAILED DESCRIPTION

Hereinafter, example embodiments will be described with reference to the accompanying drawings. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. Hereinafter, it can be understood that terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation. The same reference numerals are used for the same components in the drawings, and redundant descriptions thereof are omitted.

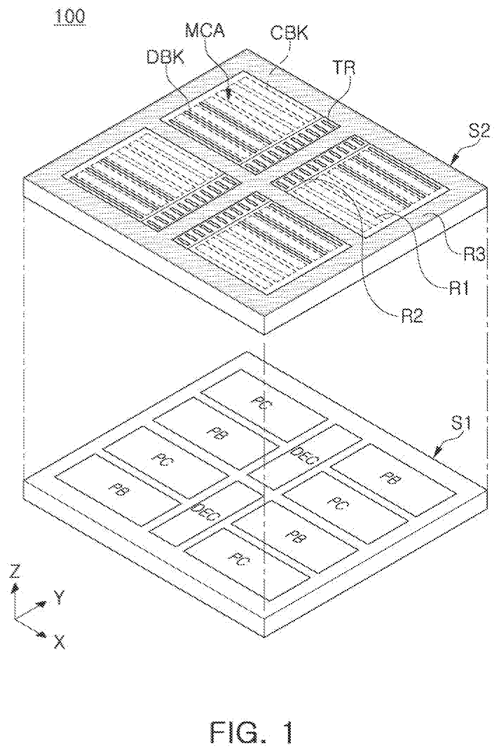

FIG. 1 is a schematic layout diagram illustrating a semiconductor device according to example embodiments.

Referring to FIG. 1, a semiconductor device 100 may include first and second semiconductor structures S1 and S2 stacked in a vertical direction. The first semiconductor structure S1 may be a peripheral circuit structure, and may include a row decoder DEC, a page buffer PB, and a peripheral circuit PC. The second semiconductor structure S2 may be a memory cell structure, and may include memory cell arrays MCA and through-wiring regions TR.

In the first semiconductor structure S1, the row decoder DEC may decode an input address, to generate and transfer driving signals of a word line. The page buffer PB may be connected to the memory cell arrays MCA through bit lines, to read information stored in memory cells. The peripheral circuit PC may be a region including a control logic and a voltage generator, and may include, for example, a latch circuit, a cache circuit, and/or a sense amplifier. A first region R1 may further include a separate pad region, and, in this case, the pad region may include an electrostatic discharge (ESD) device or a data input/output circuit.

At least a portion of the various circuit regions DEC, PB, and PC of the first semiconductor structure S1 may be disposed below the memory cell arrays MCA of the second semiconductor structure S2. For example, the page buffer PB and/or the peripheral circuit PC may be disposed below the memory cell arrays MCA to overlap the memory cell arrays MCA. According to example embodiments, circuits included in the first semiconductor structure S1 and arrangement thereof may be variously changed, and accordingly, circuits overlapping the memory cell arrays MCA may also be variously changed.

The second semiconductor structure S2 may have first to third regions R1, R2, and R3. The first region R1 may be the memory cell arrays MCA, the second region R2 may be a connection region, and the third region R3 may be an external region, adjacent to the first and second regions R1 and R2. The first region R1 may be a region in which memory cells are disposed, and the second region R2 may be a region for electrically connecting word lines to the circuit regions DEC, PB, and PC of the first semiconductor structure S1.

In the second semiconductor structure S2, the memory cell arrays MCA may be spaced apart from each other. Although four memory cell arrays MCA are illustrated as being disposed, according to example embodiments, the number and arrangement of memory cell arrays MCA disposed in the second semiconductor structure S2 may be variously changed.

The through-wiring regions TR may be regions including wiring structures passing through the second semiconductor structure S2 and connected to the first semiconductor structure S1. The first semiconductor structure S1 and the second semiconductor structure S2 may be connected to each other in each of the through-wiring regions TR. A shape, the number, arrangement, or the like of the through-wiring regions TR may be variously changed in example embodiments.

Each of the memory cell arrays MCA may include cell blocks CBK and dummy blocks DBK. The dummy blocks DBK may be blocks in which memory cells are not arranged or an operation such as storing data in the memory cells or the like is not executed.

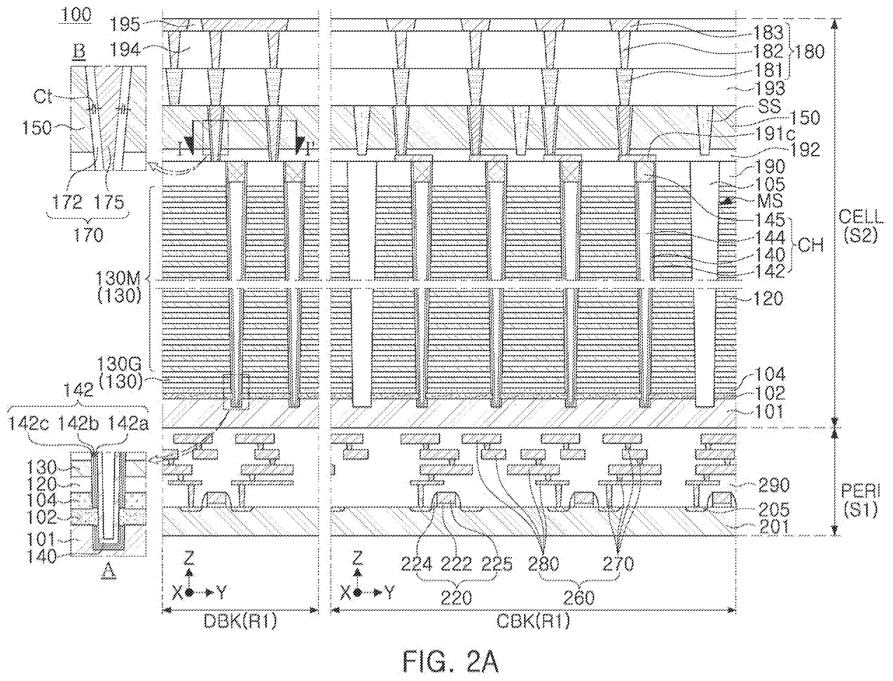

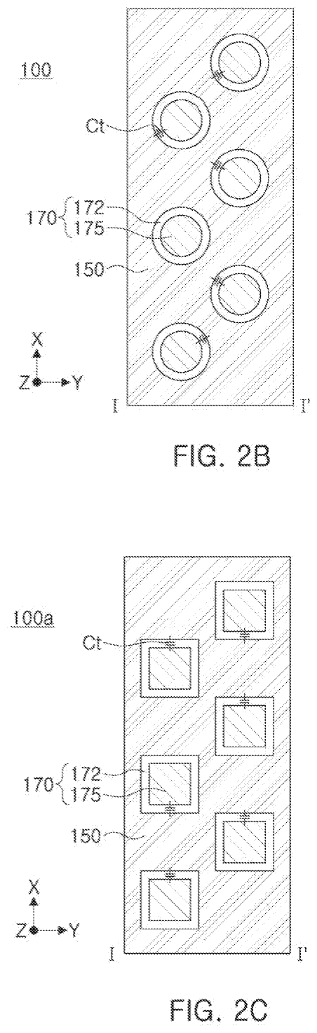

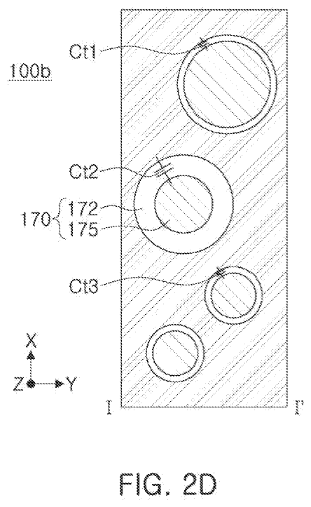

Hereinafter, example embodiments of a semiconductor device will be described with reference to FIGS. 2A and 2B.

FIG. 2A is a schematic plan view of a semiconductor device according to example embodiments. FIG. 2B is a schematic horizontal cross-sectional view of a semiconductor device according to example embodiments.

In FIG. 2A, regions indicated by ‘CBK’ and ‘DBK’ may schematically illustrate cross-sectional shapes obtained by cutting a portion of a first region R1 of memory cell arrays MCA of a semiconductor device 100 in a Y-direction, as illustrated in FIG. 1. FIG. 2B illustrates a horizontal cross-section of FIG. 2A, taken along line I-I′.

Referring to FIGS. 2A and 2B, a semiconductor device 100 may include a peripheral circuit region PERI, which is a first semiconductor structure S1 including a substrate 201, and a memory cell region CELL, which is a second semiconductor structure S2 including a plate layer 101. The memory cell region CELL may be disposed on the peripheral circuit region PERI. Conversely, in some example embodiments, the memory cell region CELL may be disposed below the peripheral circuit region PERI. The memory cell region CELL may form a portion of the first semiconductor structure S1 of FIG. 1, and the peripheral circuit region PERI may form a portion of the second semiconductor structure S2 of FIG. 1.

The peripheral circuit region PERI may include a substrate 201, source/drain regions 205 in the substrate 201, circuit elements 220 disposed on the substrate 201, circuit contact plugs 270, circuit interconnection lines 280, and a peripheral region insulating layer 290.

The substrate 201 may have an upper surface extending in X- and Y-directions. An active region may be defined on the substrate 201 by device isolation layers. The source/drain regions 205 containing impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit elements 220 may include a planar transistor. Each of the circuit elements 220 may include a circuit gate dielectric layer 222, a spacer layer 224, and a circuit gate electrode 225. The source/drain regions 205 may be disposed in the substrate 201 on both sides of the circuit gate electrode 225.

The peripheral region insulating layer 290 may be disposed on the circuit element 220 on the substrate 201. The circuit contact plugs 270 may pass through the peripheral region insulating layer 290, to be connected to the source/drain regions 205. An electrical signal may be applied to the circuit element 220 through the circuit contact plugs 270. The circuit contact plugs 270 may also be connected to the circuit gate electrode 225. The circuit interconnection lines 280 may be connected to the circuit contact plugs 270, and may be arranged as (i.e., may include) a plurality of layers.

The memory cell region CELL may include a plate layer 101, gate electrodes 130 stacked on the plate layer 101, interlayer insulating layers 120 alternately stacked with the gate electrodes 130, channel structures CH disposed to pass through a stack structure of the gate electrodes 130, upper gate electrode 150 on the interlayer insulating layers 120, and upper contact structure 170 passing through the upper gate electrode 150, and an upper capacitor structure Ct including the upper gate electrode 150 and the upper contact structure 170. The memory cell region CELL may further include separation regions MS passing through the stack structure of the gate electrodes 130.

The memory cell region CELL may further include a first horizontal conductive layer 102, a second horizontal conductive layer 104, upper separation regions SS passing through the upper gate electrode 150, a capping insulating layer 190, first to fourth upper insulating layers 192, 193, 194, and 195, and an upper interconnection structure 180.

In the plate layer 101, a first region R1 may be a region in which the gate electrodes 130 are vertically stacked and the channel structures CH are disposed, and may be a region in which memory cells are disposed, and a second region R2 may be a region in which the gate electrodes 130 extend to different lengths, and may correspond to a region for electrically connecting the memory cells to the peripheral circuit region PERI. The second region R2 may be disposed on at least one end of the first region R1 in at least one direction, for example, the X-direction.

The plate layer 101 may have a plate shape, and may function as at least a portion of a common source line of the semiconductor device 100. The plate layer 101 may include a conductive material, and may include, for example, a semiconductor material. The plate layer 101 may further include impurities. The plate layer 101 may be provided as an epitaxial layer or a polycrystalline semiconductor layer such as a polycrystalline silicon layer.

The first and second horizontal conductive layers 102 and 104 may be stacked and disposed on an upper surface of the plate layer 101. The first horizontal conductive layer 102 may function as at least a portion of a common source line of the semiconductor device 100, and may function, for example, as the common source line together with the plate layer 101. As illustrated in an enlarged view of portion ‘A’ of FIG. 2A, the first horizontal conductive layer 102 may be directly connected to a channel layer 140 around the channel layer 140.

The first and second horizontal conductive layers 102 and 104 may include a semiconductor material, and may include, for example, polycrystalline silicon. In this case, at least, the first horizontal conductive layer 102 may be a layer doped with impurities of the same conductivity type as the plate layer 101, and the second horizontal conductive layer 104 may be a doped layer or may be a layer containing impurities diffused from the first horizontal conductive layer 102. A material of the second horizontal conductive layer 104 is not limited to a semiconductor material, and may be replaced with an insulating layer according to example embodiments.

The gate electrodes 130 may be vertically spaced apart and stacked on the plate layer 101, to form a stack structure. The gate electrodes 130 may include lower gate electrodes 130G forming a gate of a ground select transistor, and memory gate electrodes 130M forming a plurality of memory cells. The number of memory gate electrodes 130M constituting memory cells may be determined according to capacity of the semiconductor device 100. According to example embodiments, the number of lower gate electrodes 130G may be 1 to 4 or more, respectively, and may have the same structure as or a different structure from the memory gate electrodes 130M. According to example embodiments, the gate electrodes 130 may further include a gate electrode 130 disposed below the lower gate electrodes 130G and constituting an erase transistor used for an erase operation using a gate induced drain leakage (GIDL) phenomenon. Also, a portion of the gate electrodes 130, e.g., memory gate electrodes 130M adjacent to the lower gate electrodes 130G, may be dummy gate electrodes.

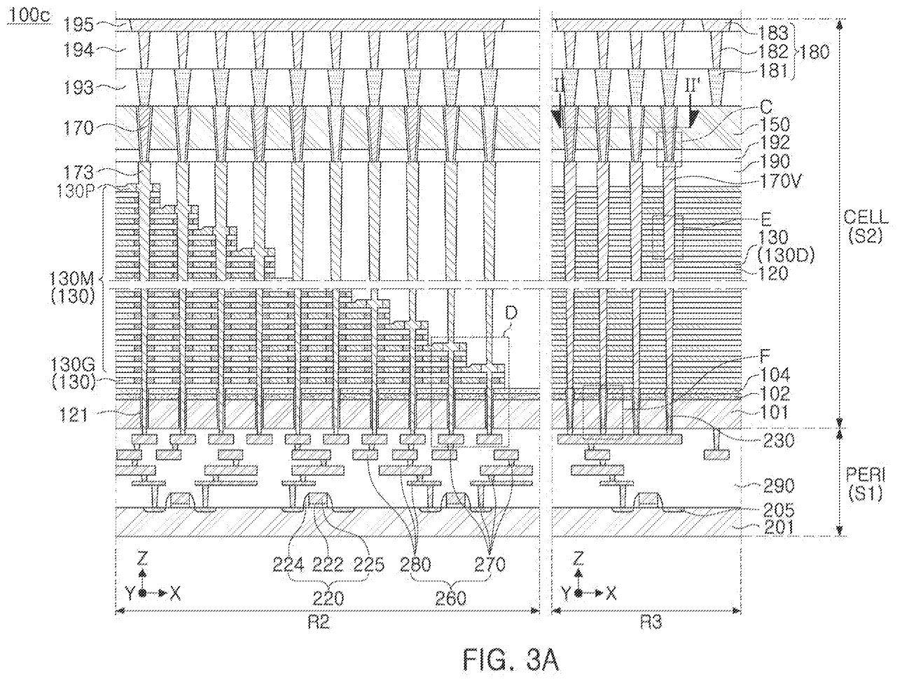

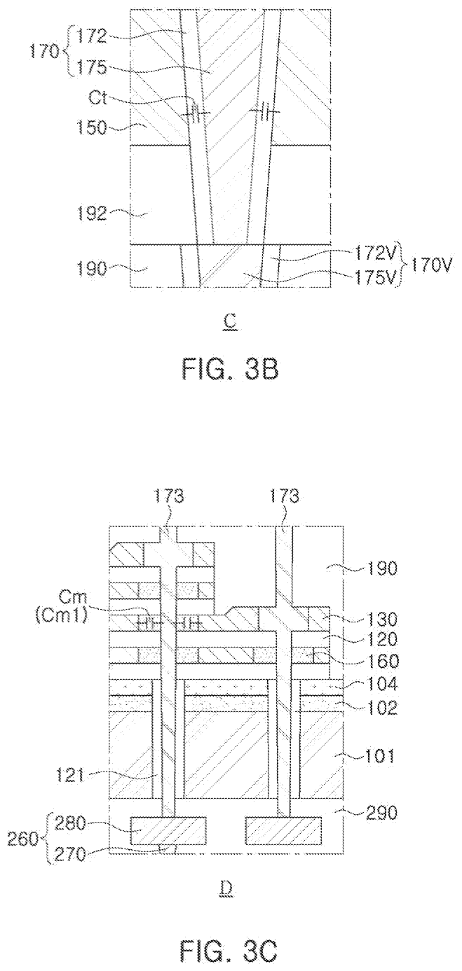

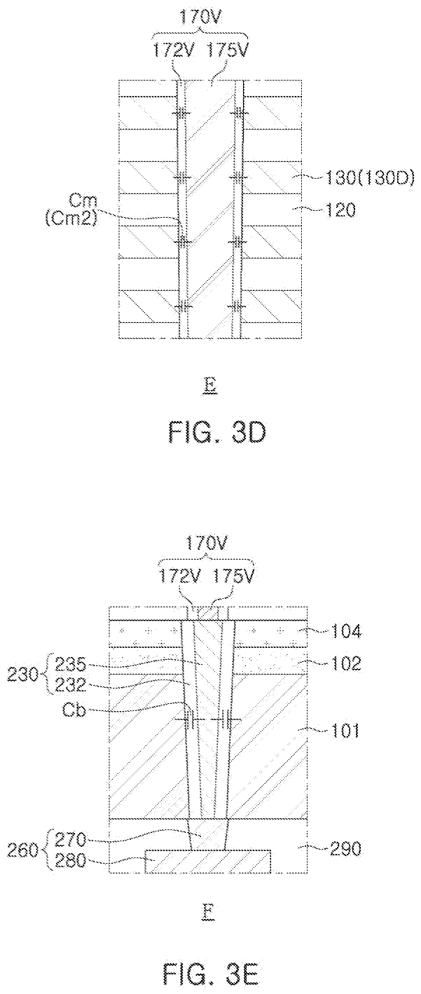

The gate electrodes 130 may be spaced apart from each other vertically and stacked in the first region R1, and may extend by different lengths from the first region R1 to the second region R2 to form a stepped structure. As illustrated in FIG. 3A, the gate electrodes 130 may form a stepped structure between the gate electrodes 130 in the X-direction, and may also be disposed to have a stepped structure from each other in the Y-direction.

Due to the stepped structure, the gate electrodes 130 may each have regions in which a lower gate electrode 130 extends further than an upper gate electrode 130 to be exposed from the interlayer insulating layers 120 in an upward direction, and the regions may be referred to as pad regions 130P. In each gate electrode 130, a pad region 130P may be a region including an end portion in the X-direction. The pad region 130P may correspond to a portion of the gate electrode 130 located in an uppermost portion among the gate electrodes 130 constituting the stack structure in the second region R2 of the plate layer 101. The gate electrodes 130 may be connected to gate contact plugs 173 in the pad regions 130P.

The gate electrodes 130 may have an increased thickness in the pad regions 130P. A thickness of each of the gate electrodes 130 may increase in such a manner that a level of a lower surface is constant and a level of an upper surface increases.

The gate electrodes 130 may be disposed to be separated from each other in the Y-direction by a separation region MS extending in the X-direction. The gate electrodes 130 between a pair of separation regions MS may form one memory block, but a range of the memory block is not limited thereto. The gate electrodes 130 may include a metal material, such as tungsten (W). According to example embodiments, the gate electrodes 130 may include polycrystalline silicon or a metal silicide material.

The interlayer insulating layers 120 may be disposed between the gate electrodes 130. Like the gate electrodes 130, the interlayer insulating layers 120 may be spaced apart from each other in a direction, perpendicular to the upper surface of the plate layer 101, and may be disposed to extend in the X-direction. The interlayer insulating layers 120 may include an insulating material such as silicon oxide or silicon nitride.

The separation regions MS may be disposed to pass through the gate electrodes 130 and extend in the X-direction. The separation regions MS may be disposed parallel to each other. The separation region MS may entirely pass through the gate electrodes 130 stacked on the plate layer 101, and may be connected to the plate layer 101. According to example embodiments, an arrangement order, the number, or the like of separation regions MS is not limited to those illustrated in FIG. 2A. A separation insulating layer 105 may be disposed in the separation regions MS.

The upper separation regions SS may be disposed to pass through the upper gate electrode 150 and extend in the X-direction. In an example embodiment, upper surfaces of the upper separation regions SS may be located on a level, substantially equal to an upper surface of the upper gate electrode 150. The upper separation regions SS may pass through the upper gate electrode 150, and may extend into the first upper insulating layer 192.

The upper separation regions SS may be located on a higher level than the separation regions MS. In a plan view, at least a portion of the upper separation regions SS may overlap the separation regions MS extending in the X-direction. A distance between adjacent separation regions MS in the Y-direction may be greater than a distance between adjacent upper separation regions SS in the Y-direction. Therefore, in a plan view, at least a portion of the upper separation regions SS may be disposed between adjacent separation regions MS. Because the upper separation regions SS and the upper gate electrode 150 may be located on a higher level than the separation regions MS and the channel structures CH, dummy structures between the channel structures CH may be omitted. In addition, the semiconductor device 100 having an improved degree of integration may be provided.

An upper separation insulating layer may be disposed in the upper separation regions SS. In an example embodiment, the upper separation insulating layer may include an insulating material such as silicon oxide or the like.

The channel structures CH may form a memory cell string, respectively, and may be spaced apart from each other while forming rows and columns on the plate layer 101. The channel structures CH may be arranged to form a lattice pattern in an X-Y plane or may be arranged in a zigzag shape in one direction. The channel structures CH may have a columnar shape, and may have inclined side surfaces that become narrower toward the plate layer 101 according to an aspect ratio. As illustrated in the enlarged view of FIG. 2A, each of the channel structures CH may further include a channel dielectric layer 142, a buried insulating layer 144 between the channel layers 140, and a channel pad 145 on an upper end of the buried insulating layer 144, in addition to the channel layer 140.

The channel layer 140 may be formed in an annular shape surrounding the buried insulating layer 144 therein, but may have a columnar shape such as a cylinder or a prism without the buried insulating layer 144 according to example embodiments. The channel layer 140 may be connected to the first horizontal conductive layer 102 in a lower portion. The channel layer 140 may include a semiconductor material such as polycrystalline silicon or single crystal silicon, and the semiconductor material may be an undoped material or a material containing p-type or n-type impurities.

The channel dielectric layer 142 may be disposed between the gate electrodes 130 and the channel layer 140. Referring to FIG. 2A, the channel dielectric layer 142 may include a tunneling layer 142a, a charge storage layer 142b, and a blocking layer 142c, sequentially stacked from the channel layer 140. The tunneling layer 142a may tunnel charges into the charge storage layer 142b, and may include, for example, silicon oxide (SiO₂), silicon nitride (Si₃N₄), silicon oxynitride (SiON), or a combination thereof. The charge storage layer 142b may be a charge trap layer or a floating gate conductive layer. The blocking layer 142c may include silicon oxide (SiO₂), silicon nitride (Si₃N₄), silicon oxynitride (SiON), a high-K dielectric material, or a combination thereof.

The channel pad 145 may be disposed to cover an upper surface of the buried insulating layer 144 and be electrically connected to the channel layer 140. The channel pad 145 may be disposed above the channel layer 140. The channel pad 145 may include, for example, polycrystalline silicon.

The upper gate electrode 150 may be disposed on the first upper insulating layer 192 and a conductive pattern 191c. The upper gate electrode 150 may be located on a higher level than the channel structures CH. A thickness of the upper gate electrode 150 may be greater than a thickness of each of the gate electrodes 130. Capacitance of the upper capacitor structure Ct, which will be described later, may be adjusted by adjusting the thickness of the upper gate electrode 150. The upper gate electrode 150 may include a material different from that of the gate electrodes 130, but is not limited thereto. For example, the upper gate electrode 150 may be a semiconductor material layer such as polycrystalline silicon or the like. The upper gate electrode 150 may include a conductive material, for example, a metal material such as tungsten (W), copper (Cu), aluminum (Al), or the like. The upper gate electrode 150 may include at least one of a doped semiconductor material, a metal (e.g., TiN or TaN), or a transition metal (e.g., Ti or Ta).

The upper contact structure 170 may include an upper contact insulating layer 172 surrounding a sidewall of the upper contact structure 170, and an upper contact plug 175 in the upper contact insulating layer 172. The upper contact insulating layer 172 may include an insulating material, and may include, for example, at least one of silicon oxide, silicon nitride, or silicon oxynitride. The upper contact plug 175 may include a conductive material, for example, a metal material such as tungsten (W), copper (Cu), aluminum (Al), or the like. A central axis of the upper contact structure 170 may be offset from a central axis of the channel structures CH. According to an example embodiment, in the dummy blocks DBK, the upper contact structure 170 may be electrically insulated from the channel structures CH. In the cell blocks CBK, the upper contact structure 170 may be electrically connected to the channel structures CH through the conductive pattern 191c.

According to an example embodiment, the semiconductor device 100 may further include a conductive pattern 191c in the cell blocks CBK. The conductive pattern 191c may pass through the first upper insulating layer 192, and may be connected to the channel structures CH. The conductive pattern 191c may be a structure filled in a plurality of holes having a shape such as a circle, an ellipse, a polygon, or the like. In a Z-direction, which is a vertical direction, the conductive pattern 191c may partially overlap the channel structures CH. The conductive pattern 191c may include a semiconductor material such as silicon (Si), germanium (Ge), or a mixture thereof. In the dummy blocks DBK, the conductive pattern 191c may not be disposed.

As illustrated in FIG. 2A, in an enlarged view of portion ‘B’ of the dummy blocks DBK, the semiconductor device 100 may include an upper capacitor structure Ct. The upper capacitor structure Ct may include an upper contact structure 170 including an upper contact insulating layer 172 and an upper contact plug 175, and an upper gate electrode 150. The upper contact plug 175 may have a potential, different from a potential of the upper gate electrode 150. The upper contact plug 175 may receive a bias through the upper interconnection structure 180 contacting the upper contact plug 175. The upper contact plug 175 may be electrically insulated from the upper gate electrode 150 by the upper contact insulating layer 172. The upper gate electrode 150 may receive a bias through the upper interconnection structure 180, but may have a potential, different from a potential of the upper contact plug 175. In the upper capacitor structure Ct, charge may be stored in the upper contact insulating layer 172 due to a potential difference between the upper contact plug 175 and the upper gate electrode 150.

The capping insulating layer 190 may be disposed to cover the plate layer 101, the gate electrodes 130 on the plate layer 101, and the peripheral region insulating layer 290. The capping insulating layer 190 may be formed of an insulating material or may be formed as a plurality of insulating layers.

The first to fourth upper insulating layers 192, 193, 194, and 195 may be formed of an insulating material or may be formed as a plurality of insulating layers. The first to fourth upper insulating layers 192, 193, 194, and 195 may include, for example, silicon oxide, silicon nitride, silicon carbide, or silicon oxynitride.

The upper interconnection structure 180 may include a stud 181 contacting the upper contact structure 170, contact plugs 182 contacting the stud 181, and an upper interconnection 183 on the contact plugs 182. The upper interconnection structure 180 may be connected to gate contact plugs 173 and through-via structures 170V, and may be electrically connected to the gate electrodes 130 and the channel structures CH. According to example embodiments, the number of contact plugs and interconnection lines constituting the upper interconnection structure may be variously changed. The upper interconnection structure 180 may include metal, for example, tungsten (W), copper (Cu), aluminum (Al), or the like.

In the descriptions of the following example embodiments, descriptions overlapping the above descriptions will be omitted.

FIGS. 2C and 2D are schematic horizontal cross-sectional views of a semiconductor device according to example embodiments. FIGS. 2C and 2D illustrate a horizontal cross-section of FIG. 2A, taken along line I-I′, respectively.

Referring to FIG. 2C, in a semiconductor device 100a, a cross-section of at least one of an upper contact structure 170 or a lower contact structure 230 in a horizontal direction parallel to an upper surface of a plate layer 101, may have a polygonal shape. A horizontal cross-section of the upper contact structure 170 may have, for example, a tetragonal shape, but is not limited thereto. According to another example embodiment, the horizontal cross-section of the upper contact structure 170 may have a triangular shape, a pentagonal shape, a hexagonal shape, or the like. An upper capacitor structure Ct may include an upper contact plug 175 having a polygonal horizontal cross-section, an upper contact insulating layer 172, and an upper gate electrode 150. The description of the upper capacitor structure Ct described above with reference to FIGS. 2A and 2B may be equally applied to the upper capacitor structure Ct. Such description may be applied to other example embodiments as well, and, for example, may also be applied to an intermediate capacitor structure Cm of a semiconductor device 100c of FIG. 3A, which will be described later.

Referring to FIG. 2D, in a semiconductor device 100b, an upper capacitor structure Ct may include upper capacitor structures Ct1, Ct2, and Ct3 having different capacitances. A capacitance may be determined according to a thickness of an upper contact insulating layer 172, a contact area between the upper contact insulating layer 172 and an upper gate electrode 150, a contact area between the upper contact insulating layer 172 and an upper contact plug 175, a material of an upper gate electrode 150, a material of the upper contact plug 175, or the like. A capacitance of the upper capacitor structure Ct may be determined according to the number of upper contact structures 170 disposed in the upper gate electrode 150, for example, a pattern density.

FIGS. 2B, 2C and 2D illustrate horizontal cross-sections of the upper contact structure 170, but are not limited thereto. The above description may be applied to a lower contact structure 230 (refer to FIG. 3E) to be described later. According to an example embodiment, the upper contact insulating layer 172 may have different thicknesses and the lower contact insulating layer 232 (see FIG. 3E) may have different thicknesses. Also, the upper contact plugs 175 may have different widths, and the lower contact plugs 235 (see FIG. 3E) may have different widths.

FIG. 3A is a schematic cross-sectional view of a semiconductor device according to example embodiments. FIGS. 3B, 3C, 3D and 3E are partial enlarged views of a semiconductor device according to example embodiments.

In FIG. 3A, a region indicated by ‘R2’ may schematically represent a cross-sectional shape obtained by cutting a portion of a second region R2 of a semiconductor device 100 in the X-direction, as illustrated in FIG. 1, and a region indicated by ‘R3’ may schematically represent a cross-sectional shape obtained by cutting a portion of a third region R3 of the semiconductor device 100 in the X-direction, as illustrated in FIG. 1. FIGS. 3B, 3C, 3D and 3E respectively enlarge and illustrate portions ‘C’, ‘D’, ‘E’, and ‘F’ of FIG. 3A.

A second region R2 and a third region R3 of a semiconductor device 100c of FIG. 3A may be applied to the second region R2 and the third region R3 of the semiconductor device 100 of FIG. 2A, but are not limited thereto.

Referring to FIGS. 3A, 3B, 3C, 3D and 3E, a semiconductor device 100c may include gate contact plugs 173 passing through gate electrodes 130, gate contact insulating layers 160 surrounding the gate contact plugs 173 in a second region R2, a plate insulating layer 121 passing through a plate layer 101, and a through-via structure 170V disposed in a third region R3 outside first and second regions R1 and R2. The semiconductor device 100c may include an upper capacitor structure Ct, an intermediate capacitor structure Cm, and a lower capacitor structure Cb in at least one of the second region R2 or the third region R3.

The gate contact plugs 173 may pass through gate electrodes 130 in an uppermost portion and gate contact insulating layers 160 therebelow in the second region R2, and may be connected to pad regions 130P of the gate electrodes 130. The gate contact plugs 173 may pass through at least a portion of a capping insulating layer 190, and may be disposed to be connected to each of the pad regions 130P of the gate electrodes 130 exposed in an upward direction. The gate contact plugs 173 may pass through the plate layer 101 and first and second horizontal conductive layers 102 and 104 below the gate electrodes 130, to form circuit interconnection lines 280 in a peripheral circuit region PERI. The gate contact plugs 173 may be spaced apart from the plate layer 101 and the first and second horizontal conductive layers 102 and 104 by the plate insulating layer 121. The gate contact plugs 173 may be surrounded by the plate insulating layer 121, and may be electrically separated from the plate layer 101.

The gate contact plugs 173 may include, for example, at least one of tungsten (W), copper (Cu), aluminum (Al), or an alloy thereof. According to example embodiments, the gate contact plugs 173 may further include barrier layers on sidewalls and bottom surfaces of contact holes in which the gate contact plugs 173 are disposed. The barrier layers may include, for example, at least one of titanium (Ti), titanium nitride (TiN), tantalum (Ta), or tantalum nitride (TaN).

The gate contact insulating layers 160 may be disposed to surround side surfaces of the gate contact plugs 173 below the pad regions 130P. Internal side surfaces of the gate contact insulating layers 160 may surround the gate contact plugs 173, and external side surfaces of the gate contact insulating layers 160 may be surrounded by the gate electrodes 130. The gate contact plugs 173 may be physically and electrically connected to one gate electrode 130 by the gate contact insulating layers 160, and may be electrically separated from the gate electrodes 130 therebelow. The gate contact insulating layers 160 may include an insulating material, and may include, for example, at least one of silicon oxide, silicon nitride, or silicon oxynitride.

The plate insulating layer 121 may extend in the Z-direction in the second region R2, and may be disposed to pass through the plate layer 101, the first horizontal conductive layer 102, and the second horizontal conductive layer 104. The plate insulating layer 121 may be disposed to surround each of the gate contact plugs 173. Therefore, the gate contact plugs 173 connected to different gate electrodes 130 may be electrically separated from each other. The plate insulating layer 121 may also be disposed in the third region R3. The plate insulating layer 121 may include, for example, silicon oxide, silicon nitride, silicon carbide, or silicon oxynitride.

Through-via structures 170V may be disposed in the third region R3 of a memory cell region CELL, which may be an external region of the plate layer 101, may pass through the capping insulating layer 190, the gate electrodes 130, and the interlayer insulating layers 120, and may extend to the peripheral circuit region PERI. The through-via structure 170V may include a through-via insulating layer 172V surrounding a sidewall of the through-via structure 170V, and a through-via plug 175V in the through-via insulating layer 172V. The through-via structures 170V may be arranged to connect an upper interconnection structure 180 of the memory cell region CELL and the circuit interconnection lines 280 of the peripheral circuit region PERI. The through-via structures 170V may include a conductive material, and may include, for example, a metal material such as tungsten (W), copper (Cu), aluminum (Al), or the like.

According to an example embodiment, in the third region R3 of the semiconductor device 100c, a lower interconnection structure 260 may include a capacitor structure. The capacitor structure may include lines and contacts disposed on a level, equal to those of circuit contact plugs 270 and those of circuit interconnection lines 280. The capacitor structure may be horizontally spaced apart from a region of the lower interconnection structure 260. The capacitor structure may be electrically connected to a portion of circuit elements 220. The capacitor structure may be disposed in the third region R3, but is not limited thereto. In some example embodiments, the capacitor structure may be disposed below the first region R1 or may be disposed below all of the first to third regions R1, R2, and R3 (see FIG. 1) of the memory cell structure CELL.

The description of the upper capacitor structure Ct of FIG. 2A described above may be applied to an upper capacitor structure Ct of FIG. 3B in the same manner.

As illustrated in FIG. 3C, a first intermediate capacitor structure Cm1 may be further included in the second region R2. The first intermediate capacitor structure Cm1 may include a gate contact plug 173, gate contact insulating layers 160, and gate electrodes 130. A bias may be applied to the gate electrodes 130 through the gate contact plug 173 contacting the gate electrodes 130. Gate electrodes 130 not contacting the gate contact plug 173 may be electrically insulated from the gate contact plug 173 by the gate contact insulating layers 160. The gate electrodes 130 not contacting the gate contact plug 173, and the gate contact plug 173 may have different potentials. The gate contact insulating layers 160 may include an insulating material, for example, silicon oxide or silicon nitride. Charges may be stored in the gate contact insulating layers 160 due to a potential difference between the gate contact plug 173 and the gate electrodes 130 not contacting the gate contact plug 173.

As illustrated in FIG. 3D, a second intermediate capacitor structure Cm2 may be further included in the third region R3. In the third region R3, gate electrodes 130 may be dummy gate electrodes 130D. In this specification, the term “dummy” may be used to refer to a component that has the same or similar structure and shape as other components, but does not perform a substantial function in a device and exists only as a pattern. A through-via structure 170V may pass through the dummy gate electrodes 130D and interlayer insulating layers 120, may be electrically connected to an upper contact plug 175, and may be insulated from the dummy gate electrodes 130D, respectively. The through-via structure 170V may include a through-via insulating layer 172V surrounding a sidewall of the through-via structure 170V, and a through-via plug 175V in the through-via insulating layer 172V. The second intermediate capacitor structure Cm2 may include the through-via plug 175V, the dummy gate electrodes 130D, and the through-via insulating layer 172V. The through-via plug 175V may receive a bias applied by an upper interconnection structure 180 and an upper contact structure 170. The through-via plug 175V and the dummy gate electrodes 130D may have different potentials. In the second intermediate capacitor structure Cm2, charges may be stored in the through-via insulating layer 172V due to a potential difference between the through-via plug 175V and the dummy gate electrodes 130D.

As illustrated in FIG. 3E, a lower capacitor structure Cb may be further included in the third region R3. The lower capacitor structure Cb may include a lower contact structure 230 including a lower contact insulating layer 232 and a lower contact plug 235, and a plate layer 101. The lower contact plug 235 may have a different potential from that of the plate layer 101. A bias may be applied to the lower contact plug 235 through a lower interconnection structure 260 contacting the lower contact plug 235. The lower contact plug 235 may be electrically insulated from the upper gate electrode 150 by the lower contact insulating layer 232. The plate layer 101 may receive a bias through the lower interconnection structure 260, but may have a different potential from that of the lower contact plug 235. In the lower capacitor structure Cb, charges may be stored in the lower contact insulating layer 232 due to a potential difference between the lower contact plug 235 and the plate layer 101.

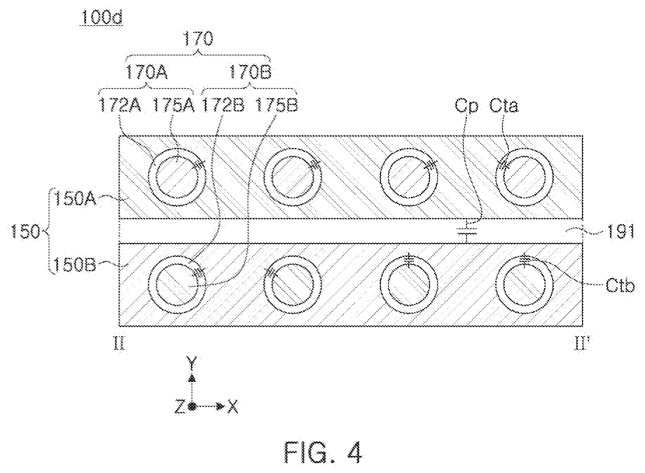

FIG. 4 is a schematic horizontal cross-sectional view of a semiconductor device according to example embodiments. FIG. 4 illustrates a horizontal cross-sectional view of FIG. 3A, taken along line II-II′.

Referring to FIG. 4, the semiconductor device 100d may further include an external capacitor structure Cp in the third region R3.

An upper gate electrode 150 may include a first upper gate electrode 150A and a second upper gate electrode 150B, having different potentials. An upper contact structure 170 may include a first upper contact structure 170A disposed in the first upper gate electrode 150A, and a second upper contact structure 170B disposed in the second upper gate electrode 150B. The first upper contact structure 170A may include a first upper contact insulating layer 172A surrounding a sidewall of the first upper contact structure 170A, and a first upper contact plug 175A in the first upper contact insulating layer 172A. The second upper contact structure 170B may include a second upper contact insulating layer 172B surrounding a sidewall of the second upper contact structure 170B, and a second upper contact plug 175B in the second upper contact insulating layer 172B.

A first upper capacitor structure Cta may include the first upper contact plug 175A, the first upper contact insulating layer 172A, and the first upper gate electrode 150A. The first upper contact plug 175A and the first upper gate electrode 150A may have different potentials. In the first upper capacitor structure Cta, charges may be stored in the first upper contact insulating layer 172A due to a potential difference between the first upper contact plug 175A and the first upper gate electrode 150A.

A second upper capacitor structure Ctb may include the second upper contact plug 175B, the second upper contact insulating layer 172B, and the second upper gate electrode 150B. The second upper contact plug 175B and the second upper gate electrode 150B may have different potentials. In the second upper capacitor structure Ctb, charges may be stored in the second upper contact insulating layer 172B due to a potential difference between the second upper contact plug 175B and the second upper gate electrode 150B.

The external capacitor structure Cp may include the first upper gate electrode 150A, the second upper gate electrode 150B, and an external insulating layer 191. The external insulating layer 191 may be disposed between the first upper gate electrode 150A and the second upper gate electrode 150B. The external insulating layer 191 may include an insulating material, for example, silicon oxide or silicon nitride. The first upper gate electrode 150A and the second upper gate electrode 150B may have different potentials. In the external capacitor structure Cp, charges may be stored in the external insulating layer 191 due to a potential difference between the first upper gate electrode 150A and the second upper gate electrode 150B.

The first upper contact plug 175A and the second upper contact plug 175B may have different potentials, but are not limited thereto.

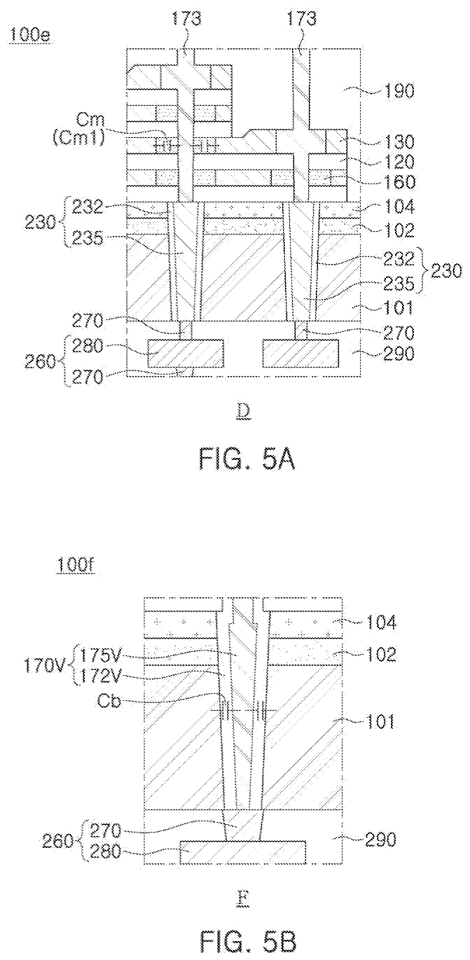

FIGS. 5A and 5B are partial enlarged views of a semiconductor device according to example embodiments. FIGS. 5A and 5B are enlarged views of regions corresponding to ‘D’ and ‘F’ of FIG. 3A, respectively.

Referring to FIG. 5A, in a second region R2 of a semiconductor device 100e, a lower contact structure 230 including a lower contact insulating layer 232 and a lower contact plug 235 may be further included, in addition to the components of the semiconductor device 100c of FIG. 3A. A gate contact plug 173 may be in contact with an upper surface of the lower contact plug 235.

Referring to FIG. 5B, a through-via plug 175V may pass through a plate layer 101 in a third region R3 of a semiconductor device 100f. In the third region R3, a lower capacitor structure Cb may include the through-via plug 175V, a through-via insulating layer 172V, and the plate layer 101. The through-via plug 175V may receive a bias applied by an upper interconnection structure 180 and an upper contact structure 170. The plate layer 101 may receive a bias through a lower interconnection structure 260. The through-via plug 175V may have a different potential from that of the plate layer 101. The through-via plug 175V may be insulated from the plate layer 101 by the through-via insulating layer 172V. In the lower capacitor structure Cb, charges may be stored in the through-via insulating layer 172V due to a potential difference between the through-via plug 175V and the plate layer 101.

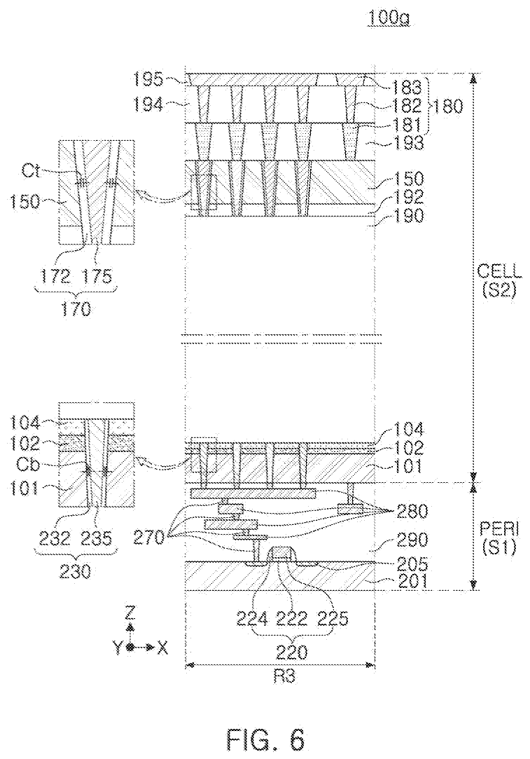

FIGS. 6, 7A, 7B, 8A, 8B, 9A and 9B are schematic cross-sectional views of a semiconductor device according to example embodiments. FIGS. 6, 7A, 7B, 8A, 8B, 9A and 9B are schematic cross-sectional views of a semiconductor device obtained by cutting a portion of a third region R3 in the X-direction, as in FIG. 1. The third region R3 may correspond to a region for electrically connecting the memory cells of the memory cell arrays MCA of FIG. 1 to a peripheral circuit.

Referring to FIG. 6, upper capacitor structures Ct may be included in a third region R3 of a semiconductor device 100g. In addition, lower capacitor structures Cb may be further included in the third region R3 of the semiconductor device 100g.

The upper capacitor structure Ct may include an upper contact structure 170 including an upper contact insulating layer 172 and an upper contact plug 175, and an upper gate electrode 150. The upper contact plug 175 may have a different potential from that of the upper gate electrode 150. The upper contact plug 175 may receive a bias through an upper interconnection structure 180 contacting the upper contact plug 175. The upper contact plug 175 may be electrically insulated from the upper gate electrode 150 by the upper contact insulating layer 172. The upper gate electrode 150 may receive a bias through the upper interconnection structure 180, but may have a different potential from that of the upper contact plug 175. In the upper capacitor structure Ct, charges may be stored in the upper contact insulating layer 172 due to a potential difference between the upper contact plug 175 and the upper gate electrode 150.

The lower capacitor structure Cb may include a lower contact structure 230 including a lower contact insulating layer 232 and a lower contact plug 235, and a plate layer 101. The plate layer 101 may include a material different from that of the upper gate electrode 150, but is not limited thereto. For example, the plate layer 101 may be a semiconductor material layer such as polycrystalline silicon or the like. The plate layer 101 may include a conductive material, and may include, for example, a metal material such as tungsten (W), copper (Cu), aluminum (Al), or the like. The plate layer 101 may include at least one of a doped semiconductor material, a metal (e.g., TiN or TaN), or a transition metal (e.g., Ti or Ta). The lower contact plug 235 may have a different potential from that of the plate layer 101. A bias may be applied to the lower contact plug 235 through a lower interconnection structure 260 contacting the lower contact plug 235. The lower contact plug 235 may be electrically insulated from the upper gate electrode 150 by the lower contact insulating layer 232. The plate layer 101 may receive a bias through the lower interconnection structure 260, but may have a different potential from that of the lower contact plug 235. In the lower capacitor structure Cb, charges may be stored in the lower contact insulating layer 232 due to a potential difference between the lower contact plug 235 and the plate layer 101.

The upper contact plug 175 and the lower contact plug 235 may be electrically insulated from each other, and the upper contact plug 175 and the lower contact plug 235 may have different potentials, but are not limited thereto.

The upper gate electrode 150 and the plate layer 101 may have different potentials, but are not limited thereto.

The upper contact insulating layer 172 and the lower contact insulating layer 232 may include an insulating material, and may include, for example, silicon oxide or silicon nitride.

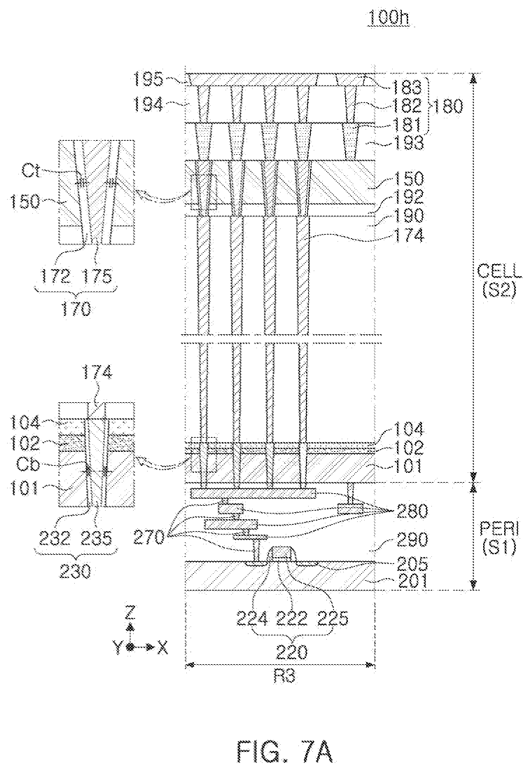

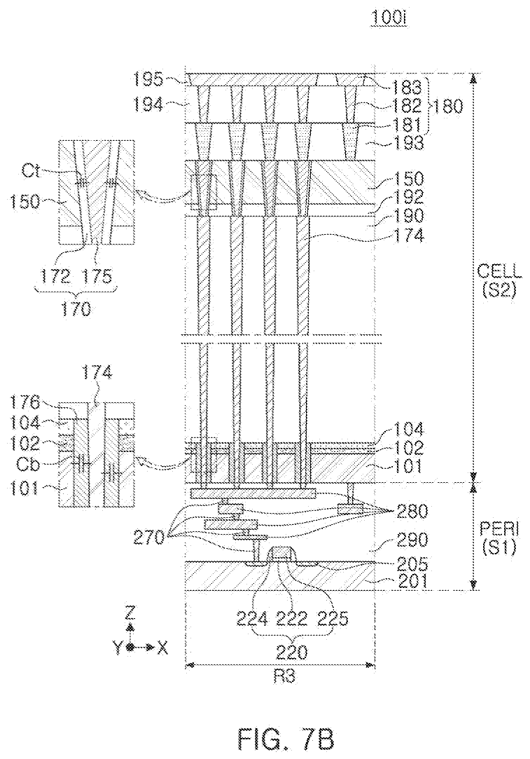

Referring to FIG. 7A, a peripheral contact plug 174 electrically connecting an upper contact plug 175 and a lower contact plug 235 may be further included in a third region R3 of a semiconductor device 100h.

The peripheral contact plug 174 may pass through a capping insulating layer 190, and may be connected to a lower contact structure 230 in the third region R3. The peripheral contact plug 174 may include a conductive material, and may include, for example, a metal material such as tungsten (W), copper (Cu), aluminum (Al), or the like.

The upper contact plug 175 may be in contact with an upper interconnection structure 180, and the lower contact plug 235 may be in contact with a lower interconnection structure 260. A bias may be applied to the upper contact plug 175 and the lower contact plug 235 through the upper interconnection structure 180 and the lower interconnection structure 260. The upper interconnection structure 180, the upper contact plug 175, the peripheral contact plug 174, and the lower contact plug 235 may have the same electric potential.

An upper capacitor structure Ct may include an upper contact structure 170 including an upper contact insulating layer 172 and the upper contact plug 175, and an upper gate electrode 150. A bias may be applied to the upper gate electrode 150 through the upper interconnection structure 180. The upper gate electrode 150 may have a different potential from that of the upper contact plug 175. The upper contact plug 175 may be electrically insulated from the upper gate electrode 150 by the upper contact insulating layer 172. In the upper capacitor structure Ct, charges may be stored in the upper contact insulating layer 172 due to a potential difference between the upper contact plug 175 and the upper gate electrode 150.

A lower capacitor structure Cb may include the lower contact structure 230 including a lower contact insulating layer 232 and the lower contact plug 235, and a plate layer 101. A bias may be applied to the plate layer 101 through the lower interconnection structure 260. The plate layer 101 may have a different potential from that of the lower contact plug 235. In the lower capacitor structure Cb, charges may be stored in the lower contact insulating layer 232 due to a potential difference between the lower contact plug 235 and the plate layer 101.

The upper gate electrode 150 and the plate layer 101 may have different potentials, but are not limited thereto.

Referring to FIG. 7B, in a semiconductor device 100i, a peripheral contact plug 174 may extend from a lower surface of an upper contact structure 170 through a capping insulating layer 190 into a plate layer 101. A peripheral contact insulating layer 176 passing through the plate layer 101 and surrounding the peripheral contact plug 174 may be disposed. A lower capacitor structure Cb may include the peripheral contact plug 174, the peripheral contact insulating layer 176, and the plate layer 101. The peripheral contact plug 174 and the plate layer 101 may have different potentials. The peripheral contact insulating layer 176 may include an insulating material, and may include, for example, silicon oxide or silicon nitride. In the lower capacitor structure Cb, charges may be stored in the peripheral contact plug 174 having different potentials and the peripheral contact insulating layer 176 of the plate layer 101.

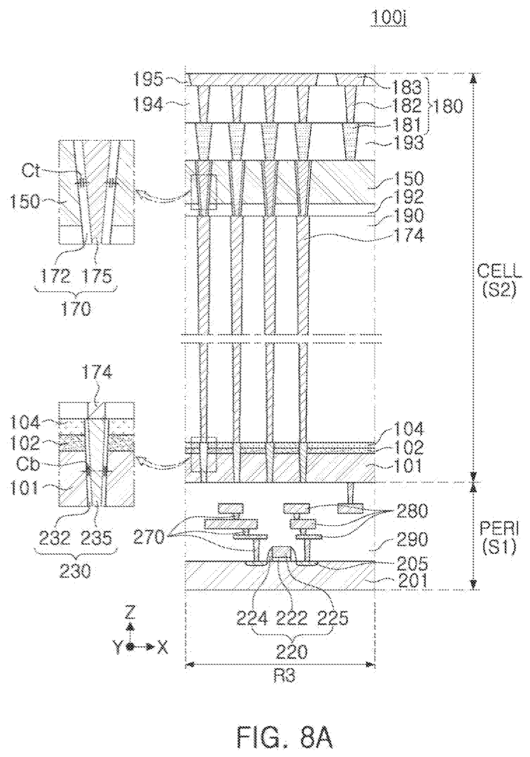

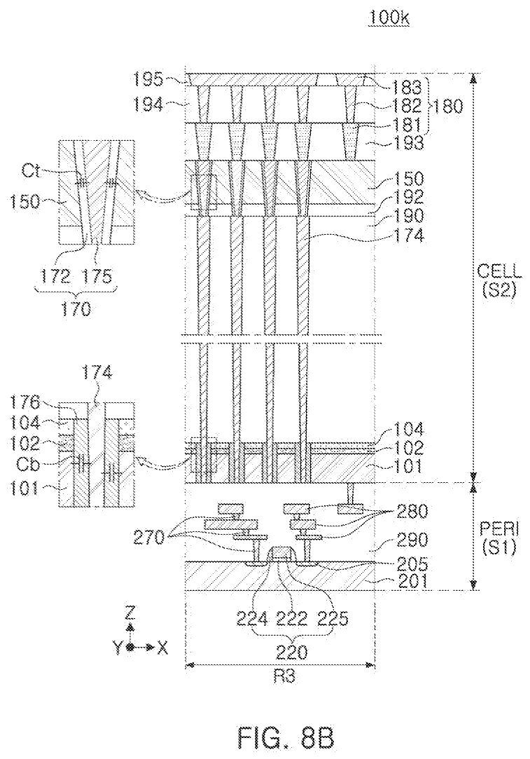

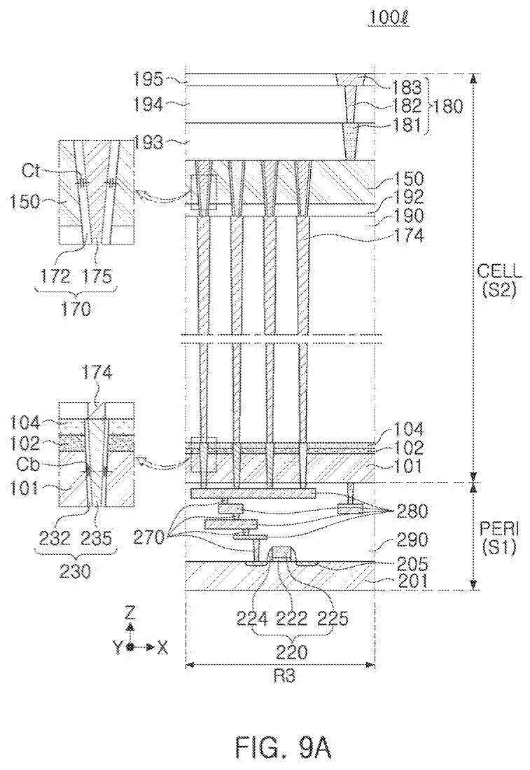

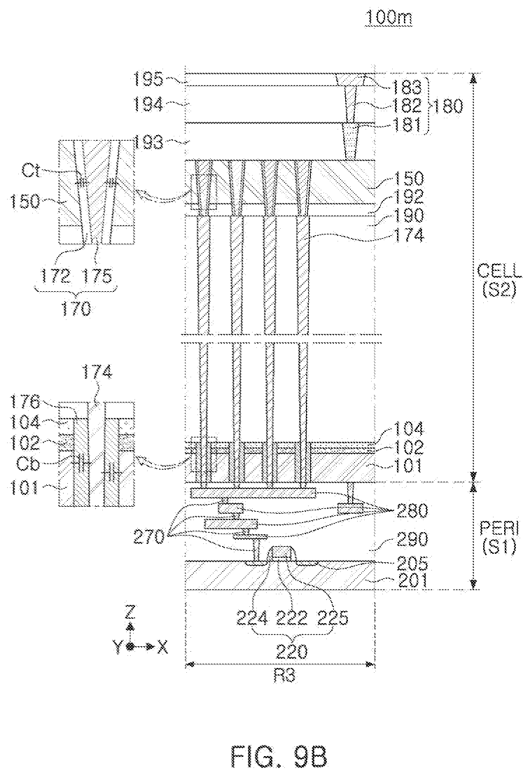

Referring to FIG. 8A, in contrast to the semiconductor device 100l of FIG. 9A, in a third region R3 of a semiconductor device 100j, a bias may be applied to an upper contact plug 175 and a lower contact plug 235 through an upper interconnection structure 180.

The lower contact plug 235 may have the same potential as the upper contact plug 175.

An upper capacitor structure Ct may include an upper contact structure 170 including an upper contact insulating layer 172 and the upper contact plug 175, and an upper gate electrode 150. A bias may be applied to the upper gate electrode 150 through the upper interconnection structure 180. The upper gate electrode 150 may have a different potential from that of the upper contact plug 175. In the upper capacitor structure Ct, charges may be stored in the upper contact insulating layer 172 due to a potential difference between the upper contact plug 175 and the upper gate electrode 150.

A lower capacitor structure Cb may include a lower contact structure 230 including a lower contact insulating layer 232 and the lower contact plug 235, and a plate layer 101. A bias may be applied to the plate layer 101 through a lower interconnection structure 260. The plate layer 101 may have a different potential from the lower contact plug 235 to which a bias is applied by the upper interconnection structure 180. In the lower capacitor structure Cb, charges may be stored in the lower contact insulating layer 232 due to a potential difference between the lower contact plug 235 and the plate layer 101.

The upper gate electrode 150 and the plate layer 101 may have different potentials, but are not limited thereto.

Referring to FIG. 8B, in a semiconductor device 100k, a peripheral contact plug 174 may pass through a plate layer 101. Hereinafter, the same content as described in FIG. 7B may be applied. The peripheral contact plug 174 may not be in contact with (i.e., may be electrically insulated from) circuit contact plugs 270 or circuit interconnection lines 280.

Referring to FIG. 9A, in contrast to the semiconductor device 100g of FIG. 7A, in a third region R3 of a semiconductor device 100l, a bias may be applied to an upper contact plug 175 and a lower contact plug 235 through a lower interconnection structure 260.

The lower interconnection structure 260, the lower contact plug 235, a peripheral contact plug 174, and the upper contact plug 175 may have the same electric potential.

An upper capacitor structure Ct may include an upper contact structure 170 including an upper contact insulating layer 172 and the upper contact plug 175, and an upper gate electrode 150. A bias may be applied to the upper gate electrode 150 through the upper interconnection structure 180. The upper gate electrode 150 may have a different potential from the upper contact plug 175 to which a bias is applied by the lower interconnection structure 260. In the upper capacitor structure Ct, charges may be stored in the upper contact insulating layer 172 due to a potential difference between the upper contact plug 175 and the upper gate electrode 150.

A lower capacitor structure Cb may include a lower contact structure 230 including a lower contact insulating layer 232 and the lower contact plug 235, and a plate layer 101. A bias may be applied to the lower contact plug 235 through the lower interconnection structure 260. The plate layer 101 may receive a bias from the lower interconnection structure 260, but may have a different potential from that of the lower contact plug 235. In the lower capacitor structure Cb, charges may be stored in the lower contact insulating layer 232 due to a potential difference between the lower contact plug 235 and the plate layer 101.

The upper gate electrode 150 and the plate layer 101 may have different potentials, but are not limited thereto.

Referring to FIG. 9B, in a semiconductor device 100m, a peripheral contact plug 174 may pass through a plate layer 101. Hereinafter, the same content as described in FIG. 7B may be applied. The peripheral contact plug 174 may not be connected to (i.e., may be electrically insulated from) an upper interconnection structure 180.

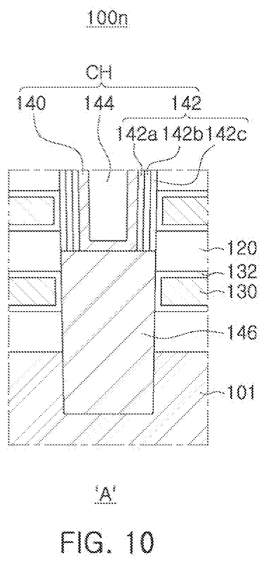

FIG. 10 is a partially enlarged view of a semiconductor device according to example embodiments. FIG. 10 illustrates a region corresponding to portion ‘A’ of FIG. 2A.

Referring to FIG. 10, a semiconductor device 100n may have a different lower structure of channel structures CH, in contrast to that of FIG. 2A. The channel structures CH may include an epitaxial layer 146, a channel layer 140, a channel dielectric layer 142, and a buried insulating layer 144. The epitaxial layer 146 may be disposed on a plate layer 101 on a lower end of the channel structures CH, and may be disposed on a side surface of at least one gate electrode 130. An insulating layer may be further disposed between the epitaxial layer 146 and the side surface of the gate electrode 130. The epitaxial layer 146 may be disposed in a recessed region of the plate layer 101. An upper surface of the epitaxial layer 146 may be located on a higher level than an upper surface of a lowermost gate electrode 130, and may be located on a lower level than a lower surface of a gate electrode 130 above the lowermost gate electrode 130, but is not limited thereto. In example embodiments, the epitaxial layer 146 may be omitted, and in this case, the channel layer 140 may be directly connected to the plate layer 101. According to example embodiments, the semiconductor device 100n may further include a gate dielectric layer 132 disposed between the gate electrodes 130 and interlayer insulating layers 120 and between the gate electrodes 130 and the channel structures CH. The gate dielectric layer 132, together with a blocking layer 142c, may serve to prevent charges in a charge storage layer 142b from moving to the gate electrodes 130.

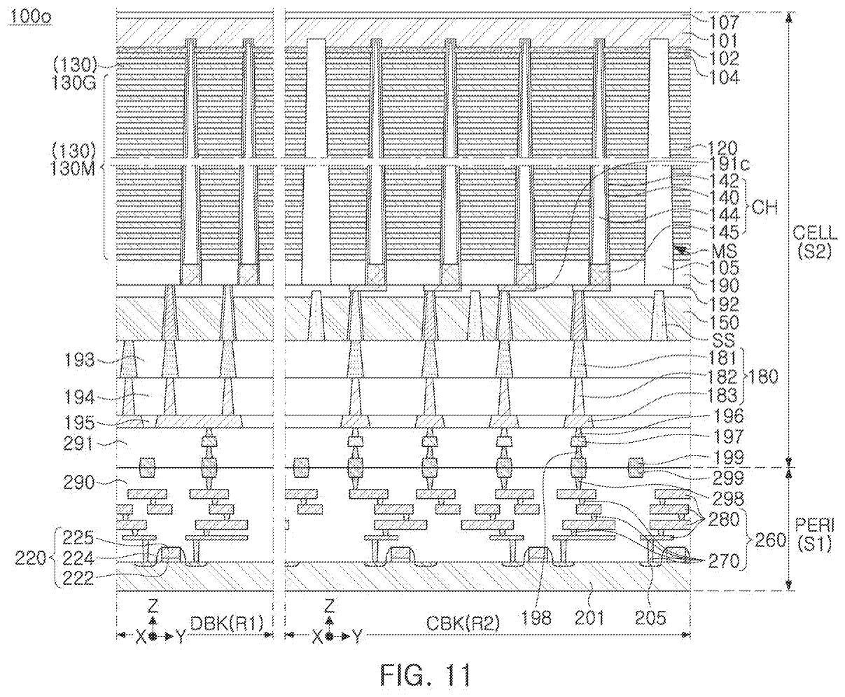

FIG. 11 is a schematic cross-sectional view of a semiconductor device according to example embodiments. FIG. 11 illustrates a region corresponding to FIG. 2A.

Referring to FIG. 11, a semiconductor device 1000 may include a first semiconductor structure S1 and a second semiconductor structure S2, which may be bonded to each other by a wafer bonding method.

The description of the peripheral circuit region PERI described above with reference to FIG. 2A may be applied to the first semiconductor structure S1. The first semiconductor structure S1 may further include first bonding vias 298 and first bonding pads 299 that may be bonding structures. The first bonding vias 298 may be disposed above uppermost circuit interconnection lines 280, and may be connected to circuit interconnection lines 280. At least a portion of the first bonding pads 299 may be connected to the first bonding vias 298 on the first bonding vias 298. The first bonding pads 299 may be connected to second bonding pads 199 of the second semiconductor structure S2. The first bonding pads 299, together with the second bonding pads 199, may provide an electrical connection path according to bonding of the first semiconductor structure S1 and the second semiconductor structure S2. The first bonding vias 298 and the first bonding pads 299 may include a conductive material, such as copper (Cu).

For the second semiconductor structure S2, unless otherwise described, the description referring to FIGS. 1, 2A and 2B may be equally applied. An upper interconnection structure of the second semiconductor structure S2 may further include a conductive line 197 and a conductive via 196 connected to an upper interconnection 183. The conductive line 197 may include a plurality of conductive lines disposed on different levels, in contrast to those illustrated. In addition, the second semiconductor structure S2 may further include second bonding vias 198 and second bonding pads 199 that may be bonding structures. The second semiconductor structure S2 may further include a protective layer 107 covering an upper surface of a plate layer 101.

The second bonding vias 198 and the second bonding pads 199 may be disposed below a lowermost conductive line 197. The second bonding vias 198 may be connected to the conductive line 197 and the second bonding pads 199, and the second bonding pads 199 may be bonded to the first bonding pads 299 of the first semiconductor structure S1. The second bonding vias 198 and the second bonding pads 199 may include a conductive material, such as copper (Cu).

The first semiconductor structure S1 and the second semiconductor structure S2 may be bonded by copper (Cu)-copper (Cu) bonding by the first bonding pads 299 and the second bonding pads 199. In addition to the copper (Cu)-copper (Cu) bonding, the first semiconductor structure S1 and the second semiconductor structure S2 may additionally be bonded to each other by dielectric-dielectric bonding. The dielectric-dielectric bonding may form a portion of a peripheral region insulating layer 290 and a portion of a bonding insulating layer 291, and may be bonding by dielectric layers respectively surrounding the first bonding pads 299 and the second bonding pads 199. Therefore, the first semiconductor structure S1 and the second semiconductor structure S2 may be bonded to each other without a separate adhesive layer.

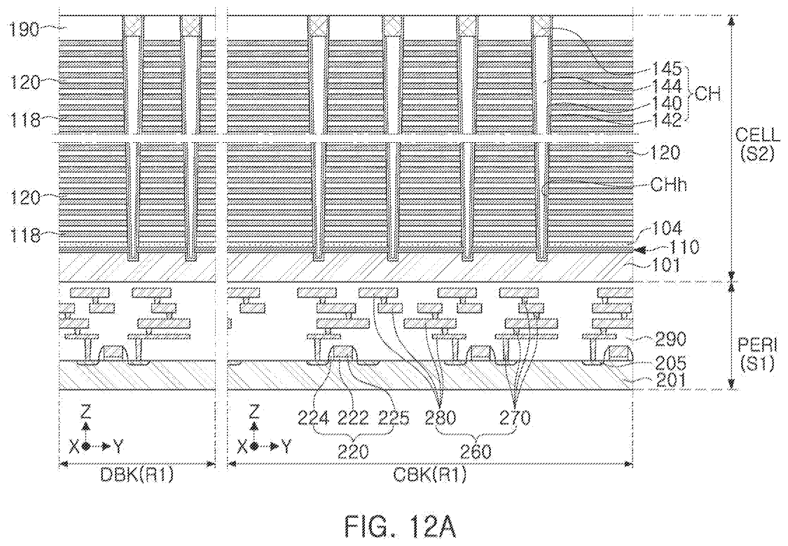

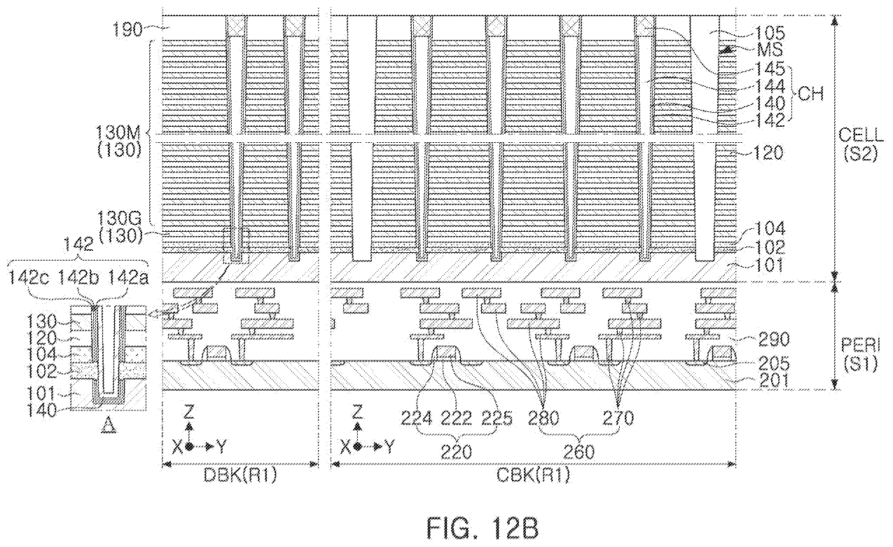

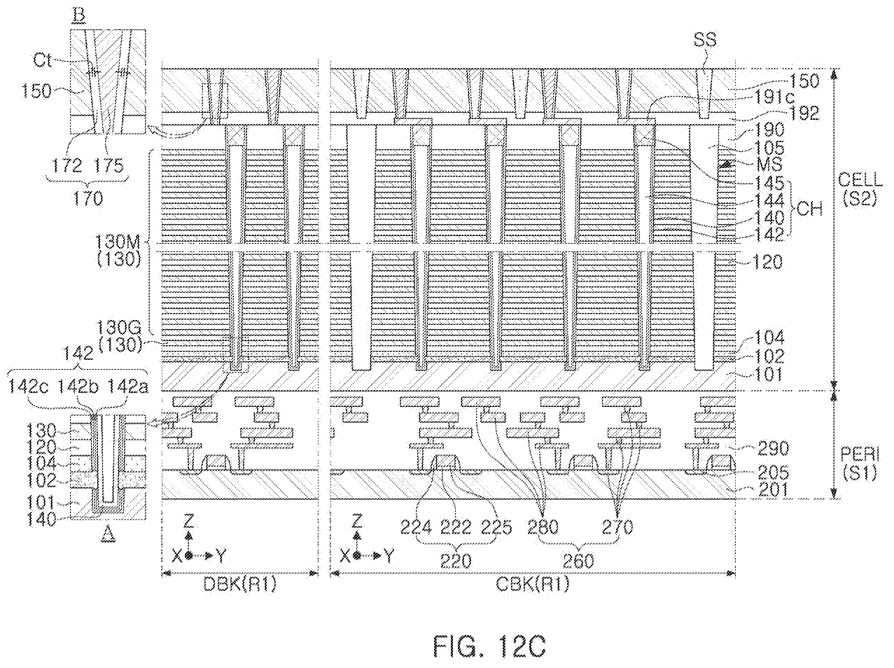

FIGS. 12A, 12B and 12C are schematic cross-sectional views illustrating a method of manufacturing a semiconductor device according to an example embodiment.

Referring to FIG. 12A, a peripheral circuit region PERI including circuit elements 220 and lower interconnection structures may be formed on a substrate 201, and a memory cell region CELL provided on the peripheral circuit region PERI may form a plate layer 101, horizontal sacrificial layers 110, and second horizontal conductive layer 104, may alternately stack sacrificial insulating layers 118 and interlayer insulating layers 120, and may form channel structures CH.

First, a circuit gate dielectric layer 222 and a circuit gate electrode 225 may be sequentially formed on the substrate 201. Also, device isolation layers may be formed. The device isolation layers may be formed by, for example, a shallow trench isolation (STI) process. The circuit gate dielectric layer 222 and the circuit gate electrode 225 may be formed using atomic layer deposition (ALD) or chemical vapor deposition (CVD). The circuit gate dielectric layer 222 may be formed of silicon oxide, and the circuit gate electrode 225 may be formed of at least one of polycrystalline silicon or a metal silicide layer, but is not limited thereto. Next, a spacer layer 224 and source/drain regions 205 may be formed on both sidewalls of the circuit gate dielectric layer 222 and both sidewalls of the circuit gate electrode 225. According to example embodiments, the spacer layer 224 may be formed as (i.e., may include) a plurality of layers. Next, the source/drain regions 205 may be formed by performing an ion implantation process.

Among the lower interconnection structures, circuit contact plugs 270 may be prepared by forming a portion of a peripheral region insulating layer 290, removing the portion by etching, and filling a conductive material. Circuit interconnection lines 280 may be formed by, for example, depositing and then patterning a conductive material.

The peripheral region insulating layer 290 may be formed as a plurality of insulating layers. The peripheral region insulating layer 290 may be partially formed in each operation of forming the lower interconnection structures, and may be partially formed above an uppermost circuit interconnection line 280, to be finally formed to cover the circuit elements 220 and the lower interconnection structures.

Next, the plate layer 101 may be formed on the peripheral region insulating layer 290. The plate layer 101 may be formed of, for example, polycrystalline silicon, and may be formed by a CVD process. The polycrystalline silicon constituting the plate layer 101 may include impurities.

The horizontal sacrificial layers 110 may include first to third horizontal sacrificial layers sequentially formed on the plate layer 101. The second horizontal sacrificial layer may include a material different from that of the first horizontal sacrificial layer and the third horizontal sacrificial layer. The horizontal sacrificial layers 110 may be layers to be replaced with a first horizontal conductive layer 102 (see FIG. 2A) by a subsequent process. For example, the first and third horizontal sacrificial layers may be formed of the same material as the interlayer insulating layers 120, and the second horizontal sacrificial layer may be formed of the same material as the sacrificial insulating layers 118. The second horizontal conductive layer 104 may be formed on the horizontal sacrificial layers 110.

A portion of the sacrificial insulating layers 118 may be replaced with gate electrodes 130 (see FIG. 2A) by a subsequent process. The sacrificial insulating layers 118 may be formed of a material different from that of the interlayer insulating layers 120, and may be formed of a material that may be etched with etch selectivity for the interlayer insulating layers 120 under specific etching conditions. For example, the interlayer insulating layer 120 may be formed of at least one of silicon oxide or silicon nitride, and the sacrificial insulating layers 118 may be formed of a material selected from silicon, silicon oxide, silicon carbide, and silicon nitride, different from the interlayer insulating layer 120. In some example embodiments, the interlayer insulating layers 120 may not all have the same thickness. Thicknesses of the interlayer insulating layers 120 and the sacrificial insulating layers 118, and the number of layers constituting them may be variously changed from those illustrated.

Next, a portion of a capping insulating layer 190 covering a stack structure of the sacrificial insulating layers 118 and the interlayer insulating layers 120 may be formed, and openings corresponding to channel holes CHh may be formed. The channel holes CHh may be formed in a hole shape by anisotropically etching the sacrificial insulating layers 118 and the interlayer insulating layers 120 using a mask layer. Due to a height of the stack structure, sidewalls of the channel holes CHh may not be perpendicular to an upper surface of the plate layer 101. The channel holes CHh may be formed to recess a portion of the plate layer 101. Next, a channel dielectric layer 142, a channel layer 140, a buried insulating layer 144, and a channel pad 145 may be sequentially formed in the channel holes CHh. The channel dielectric layer 142 may be formed to have a uniform thickness using an ALD process or a CVD process. The channel layer 140 may be formed on the channel dielectric layer 142 in the channel structures CH. The buried insulating layer 144 may be formed to fill the channel structures CH, and may be an insulating material. The channel pad 145 may be formed of a conductive material, and may be formed of, for example, polycrystalline silicon.

Referring to FIG. 12B, openings passing through the stack structure of the sacrificial insulating layers 118 and the interlayer insulating layers 120 may be formed in regions corresponding to separation regions MS (see FIG. 2A), A first horizontal conductive layer 102 and gate electrodes 130 may be formed. Next, a separation insulating layer 105 may be formed in the separation regions MS.

First, on the channel structures CH, a mask layer may be formed and openings may be formed by performing an etching operating using the mask layer. The openings may be formed to extend in the X-direction through the stack structure of the sacrificial insulating layers 118 and the interlayer insulating layers 120 and through the second horizontal conductive layer 104 from a lower portion. Next, while forming separate sacrificial spacer layers in the openings, a second horizontal sacrificial layer may be exposed by an etch-back process. The exposed second horizontal sacrificial layer may be selectively removed, and then first and third horizontal sacrificial layers, above and below the same, may be removed. The horizontal sacrificial layers 110 may be removed by, for example, a wet etching process. During the removal process of the horizontal sacrificial layers 110, a portion of the channel dielectric layer 142 exposed in the region from which the horizontal sacrificial layers 110 is removed may also be removed. After forming the first horizontal conductive layer 102 by depositing a conductive material in the region from which the horizontal sacrificial layers 110 is removed, the sacrificial spacer layers may be removed from the openings. Next, tunnel portions may be formed by removing the sacrificial insulating layers 118 exposed through the openings, and the gate electrodes 130 may be formed by filling the tunnel portions with a conductive material. The tunnel portions may be formed, for example, by a wet etching process of selectively removing the sacrificial insulating layers 118 with respect to the interlayer insulating layers 120. The conductive material constituting the gate electrodes 130 may include metal, polycrystalline silicon, or a metal silicide material.

In an example embodiment, a portion of the gate electrodes 130 may be removed from the openings together with the conductive material. The gate electrodes 130 may include regions partially recessed from the openings, as compared to the interlayer insulating layers 120.

Next, the separation insulating layer 105 may be formed by filling the openings with an insulating material and performing a planarization process to remove the mask layer and the insulating material. The insulating material may include silicon oxide, silicon nitride, or silicon oxynitride. According to example embodiments, the openings may be filled with a conductive material in addition to the insulating material.

The planarization process may be performed such that upper surfaces of the separation insulating layers 105 in the separation regions MS may be located on a level, substantially equal to upper surfaces of the channel structures CH.

Referring to FIG. 12C, an upper gate electrode 150, upper separation regions SS, and an upper contact structure 170 may be formed.

A first upper insulating layer 192 and the upper gate electrode 150 may be sequentially formed on the separation regions MS, the channel structures CH, and the capping insulating layer 190 by a deposition process.

Trenches exposing the first upper insulating layer 192 through the upper gate electrode 150 may be prepared to form regions corresponding to the upper separation regions SS, an insulating material may be deposited in the trenches, and a planarization process may be performed, to form the upper separation regions SS.

Holes passing through the upper gate electrode 150 and the first upper insulating layer 192 may be formed. The holes may expose the first upper insulating layer 192. A central axis of the holes may be offset from a central axis of the channel structures CH. In cell blocks CBK, a portion of the first upper insulating layer 192 exposed through the holes may be removed to form a region corresponding to a conductive pattern 191c. After the conductive pattern 191c is formed, the upper contact structure 170 may be prepared by forming an upper contact insulating layer 172 on sidewalls of the holes, and forming an upper contact plug 175 to fill the holes.

In dummy blocks DBK, a process of forming the conductive pattern 191c may be omitted, and the upper contact structure 170 may be formed. The central axis of the upper contact structure 170 may be offset from the central axis of the channel structures CH. The upper contact structure 170 may be spaced apart from the channel structures CH. Therefore, capacitance may be secured using an upper capacitor structure Ct including the upper contact plug 175, the upper contact insulating layer 172, and the upper gate electrode 150.

Next, referring to FIG. 2A together, the semiconductor device 100 of FIGS. 1 to 2B may be prepared by forming a second upper insulating layer 193 on the upper gate electrode 150, forming a stud 181 passing through the second upper insulating layer 193 and contacting the upper contact structure 170, and forming a third upper insulating layer 194 covering the second upper insulating layer 193, contact plugs 182 passing through the third upper insulating layer 194 and contacting the stud 181, a fourth upper insulating layer 195 covering the third upper insulating layer 194, and an upper interconnection 183 passing through the fourth upper insulating layer 195 and on the contact plugs 182, to form an upper interconnection structure 180. Because the semiconductor device 100 may include at least one of the upper gate electrode 150, the plate layer 101, and the dummy gate electrodes 130D in at least one of the first to third regions R1 to R3, to form a capacitor structure, capacitance may be sufficiently secured, stability of the peripheral circuit region PERI may be secured, and a degree of integration and electrical characteristics may be improved.

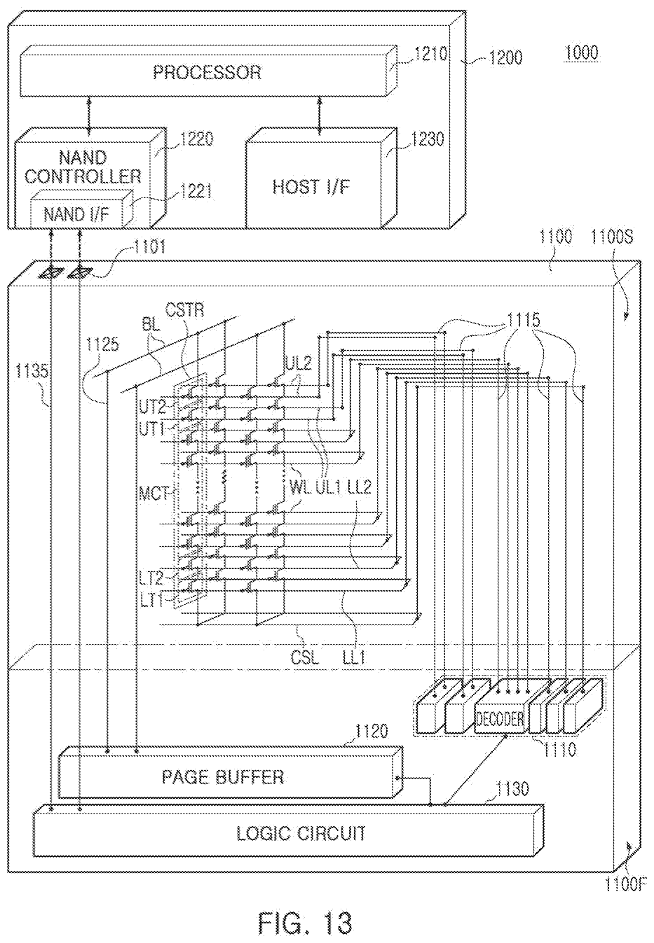

FIG. 13 is a view schematically illustrating a data storage system including a semiconductor device according to example embodiments.

Referring to FIG. 13, a data storage system 1000 may include a semiconductor device 1100, and a controller 1200 electrically connected to the semiconductor device 1100. The data storage system 1000 may be a storage device including the semiconductor device 1100 as a single semiconductor device or a plurality of semiconductor devices, or an electronic device including the storage device. For example, the data storage system 1000 may be a solid state drive device (SSD), a universal serial bus (USB), a computing system, a medical device, or a communication device, including the semiconductor device 1100 as a single semiconductor device or a plurality of semiconductor devices.

The semiconductor device 1100 may be a non-volatile memory device, for example, a NAND flash memory device described above with reference to FIGS. 1 to 11. The semiconductor device 1100 may include a first semiconductor structure 1100F, and a second semiconductor structure 1100S on the first semiconductor structure 1100F. In example embodiments, the first semiconductor structure 1100F may be disposed next to the second semiconductor structure 1100S. The first semiconductor structure 1100F may be a peripheral circuit structure including a decoder circuit 1110, a page buffer 1120, and a logic circuit 1130. The second semiconductor structure 1100S may be a memory cell structure including bit lines BL, a common source line CSL, word lines WL, first and second upper gate lines UL1 and UL2, first and second lower gate lines LL1 and LL2, and memory cell strings CSTR between each of the bit lines BL and the common source line CSL.

In the second semiconductor structure 1100S, each of the memory cell strings CSTR may include lower transistors LT1 and LT2 adjacent to the common source line CSL, upper transistors UT1 and UT2 adjacent to each of the bit lines BL, and a plurality of memory cell transistors MCT disposed between each of the lower transistors LT1 and LT2 and each of the upper transistors UT1 and UT2. The number of lower transistors LT1 and LT2 and the number of upper transistors UT1 and UT2 may be variously changed according to example embodiments.

In example embodiments, each of the upper transistors UT1 and UT2 may include a string select transistor, and each of the lower transistors LT1 and LT2 may include a ground select transistor. The lower gate lines LL1 and LL2 may be gate electrodes of the lower transistors LT1 and LT2, respectively. The word lines WL may be gate electrodes of the memory cell transistors MCT, and the upper gate lines UL1 and UL2 may be gate electrodes of the upper transistors UT1 and UT2, respectively.

In example embodiments, the lower transistors LT1 and LT2 may include a lower erase control transistor LT1 and a ground select transistor LT2, connected in series. The upper transistors UT1 and UT2 may include a string select transistor UT1 and an upper erase control transistor UT2, connected in series. At least one of the lower erase control transistor LT1 or the upper erase control transistor UT2 may be used for an erase operation of erasing data stored in the memory cell transistors MCT using a gate-induced-drain-leakage (GIDL) phenomenon.

The common source line CSL, the first and second lower gate lines LL1 and LL2, the word lines WL, and the first and second upper gate lines UL1 and UL2 may be electrically connected to the decoder circuit 1110 through first connection interconnections 1115 extending from the first semiconductor structure 1100F into the second semiconductor structure 1100S. The bit lines BL may be electrically connected to the page buffer 1120 through second connection interconnections 1125 extending from the first semiconductor structure 1100F into the second semiconductor structure 1100S.

In the first semiconductor structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through input/output connection interconnections 1135 extending from the first semiconductor structure 1100F into the second semiconductor structure 1100S.

The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined firmware, and may access to the semiconductor device 1100 by controlling the NAND controller 1220. The NAND controller 1220 may include a NAND interface 1221 processing communications with the semiconductor device 1100. A control command for controlling the semiconductor device 1100, data to be written to the memory cell transistors MCT of the semiconductor device 1100, data to be read from the memory cell transistors MCT of the semiconductor device 1100, or the like may be transmitted through the NAND interface 1221. The host interface 1230 may provide a communication function between the data storage system 1000 and an external host. When a control command is received from the external host through the host interface 1230, the processor 1210 may control the semiconductor device 1100 in response to the control command.

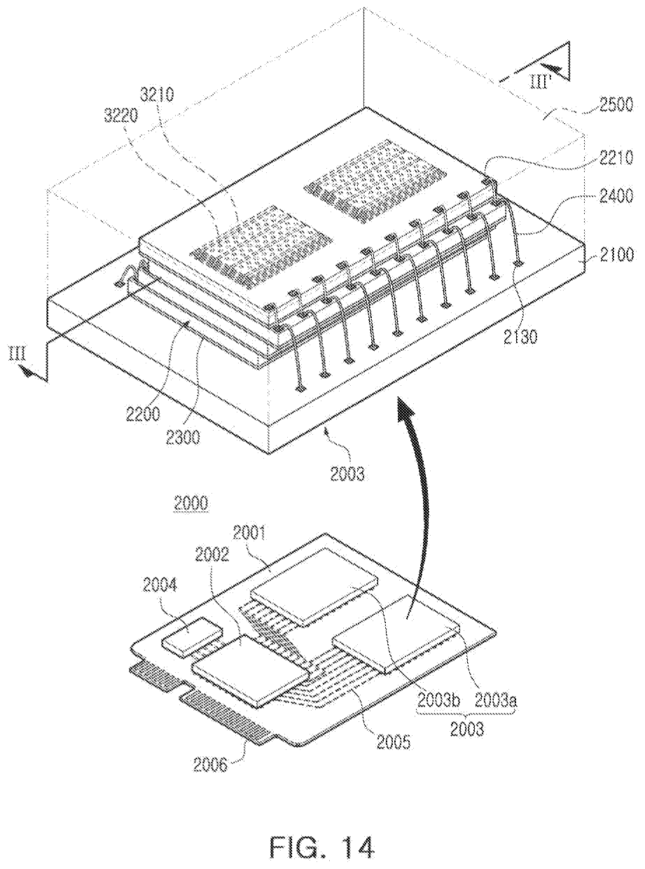

FIG. 14 is a perspective view schematically illustrating a data storage system including a semiconductor device according to example embodiments.

Referring to FIG. 14, a data storage system 2000 according to an example embodiment may include a main substrate 2001, a controller 2002 mounted on the main substrate 2001, at least one semiconductor package 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins, which may be coupled to an external host. The number and arrangement of the plurality of pins in the connector 2006 may vary according to a communication interface between the data storage system 2000 and the external host. In example embodiments, the data storage system 2000 may be communicated with the external host according to any one interface of a universal serial bus (USB), peripheral component interconnect express (PCI-Express), serial advanced technology attachment (SATA), M-Phy for universal flash storage (UFS), or the like. In example embodiments, the data storage system 2000 may be operated by power supplied from the external host through the connector 2006. The data storage system 2000 may further include a power management integrated circuit (PMIC) distributing power, supplied from the external host, to the controller 2002 and the semiconductor package 2003.

The controller 2002 may write data to the semiconductor package 2003 or read data from the semiconductor package 2003, and may improve an operation speed of the data storage system 2000.

The DRAM 2004 may be a buffer memory reducing a difference in speed between the semiconductor package 2003, which may be a data storage space, and the external host. The DRAM 2004 included in the data storage system 2000 may also operate as a type of cache memory, and may provide a space temporarily storing data in a control operation on the semiconductor package 2003. When the DRAM 2004 is included in the data storage system 2000, the controller 2002 may further include a DRAM controller controlling the DRAM 2004 in addition to a NAND controller controlling the semiconductor package 2003.

The semiconductor package 2003 may include first and second semiconductor packages 2003a and 2003b, spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting each of the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input/output pad 2210. The input/output pad 2210 may correspond to the input/output pad 1101 of FIG. 13. Each of the semiconductor chips 2200 may include gate stack structures 3210 and channel structures 3220. Each of the semiconductor chips 2200 may include the semiconductor device described above with reference to FIGS. 1 to 11.

In example embodiments, the connection structure 2400 may be a bonding wire electrically connecting the input/output pad 2210 and the upper package pads 2130. Therefore, in each of the first and second semiconductor packages 2003a and 2003b, the semiconductor chips 2200 may be electrically connected to each other by a bonding wire process, and may be electrically connected to the package upper pads 2130 of the package substrate 2100. According to example embodiments, in each of the first and second semiconductor packages 2003a and 2003b, the semiconductor chips 2200 may be electrically connected to each other by a connection structure including a through silicon via (TSV), instead of a connection structure 2400 by a bonding wire process.

In example embodiments, the controller 2002 and the semiconductor chips 2200 may be included in one (1) package. In an example embodiment, the controller 2002 and the semiconductor chips 2200 may be mounted on a separate interposer substrate, different from the main substrate 2001, and the controller 2002 and the semiconductor chips 2200 may be connected to each other by a wiring formed on the interposer substrate.

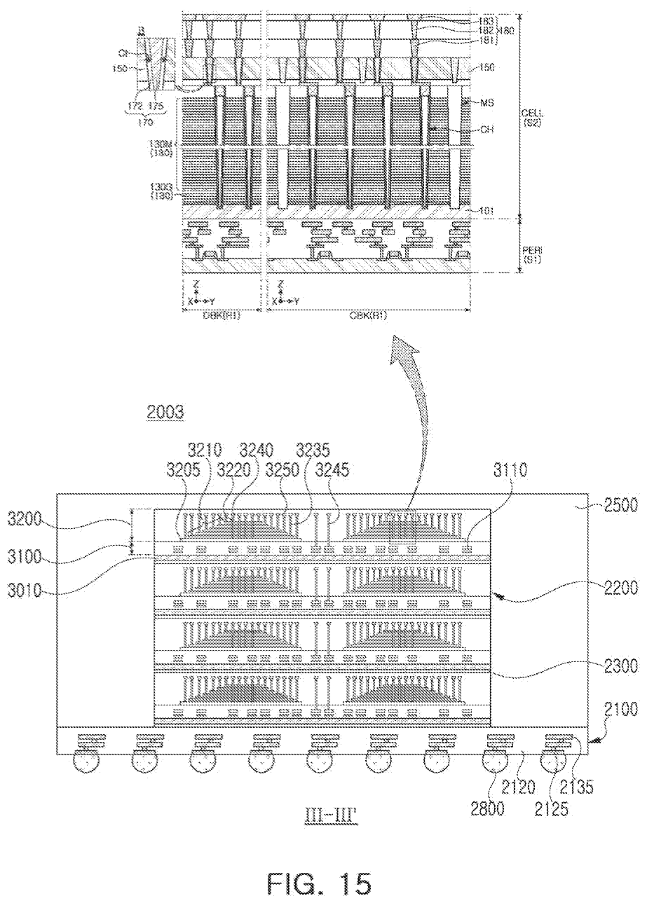

FIG. 15 is a cross-sectional view schematically illustrating a semiconductor package according to example embodiments. FIG. 15 illustrates an example embodiment of the semiconductor package 2003 of FIG. 14, and conceptually illustrates a region taken along line III-III′ of the semiconductor package 2003 of FIG. 14.

Referring to FIG. 15, in the semiconductor package 2003, the package substrate 2100 may be a printed circuit board. The package substrate 2100 may include a package substrate body portion 2120, package upper pads 2130 (refer to FIG. 14) disposed on an upper surface of the package substrate body portion 2120, lower pads 2125 disposed on a lower surface of the package substrate body portion 2120 or exposed from the lower surface, and internal interconnections 2135 electrically connecting the upper pads 2130 and the lower pads 2125 in the package substrate body portion 2120. The upper pads 2130 may be electrically connected to the connection structures 2400. The lower pads 2125 may be connected to the wiring patterns 2005 of the main substrate 2001 of the data storage system 2000, as illustrated in FIG. 14, through conductive connection portions 2800.

Each of the semiconductor chips 2200 may include a semiconductor substrate 3010, and a first semiconductor structure 3100 and a second semiconductor structure 3200 sequentially stacked on the semiconductor substrate 3010. The first semiconductor structure 3100 may include a peripheral circuit region including peripheral interconnections 3110. The second semiconductor structure 3200 may include a common source line 3205, a gate stack structure 3210 on the common source line 3205, channel structures 3220 and separation regions 3230, passing through the gate stack structure 3210, bit lines 3240 electrically connected to the memory channel structures 3220, and contact plugs 3235 electrically connected to word lines WL (see FIG. 13) of the gate stack structure 3210. As described above with reference to FIGS. 1 to 11, an upper capacitor structure Ct in each of the semiconductor chips 2200 may include an upper contact plug 175, an upper contact insulating layer 172, and an upper gate electrode 150. Due to this, capacitance may be sufficiently secured, stability of the peripheral circuit region PERI may be secured, and a degree of integration and electrical characteristics may be improved.

Each of the semiconductor chips 2200 may include a through-interconnection 3245 electrically connected to the peripheral interconnections 3110 of the first semiconductor structure 3100 and extending into the second semiconductor structure 3200. The through-interconnection 3245 may be disposed outside the gate stack structure 3210, and may further be disposed to pass through the gate stack structure 3210. Each of the semiconductor chips 2200 may further include an input/output pad 2210 (see FIG. 14) electrically connected to the peripheral interconnections 3110 of the first semiconductor structure 3100.

A semiconductor device having improved electrical characteristics and a degree of integration and an electronic system including the same may be provided by including an upper capacitor structure including an upper gate electrode and an upper contact structure and/or a lower capacitor structure including a plate layer and a lower contact structure.

While aspects of example embodiments have been particularly shown and described, it will be understood that various changes in form and details may be made therein without departing from the spirit and scope of the following claims.

What is claimed is:

1. A semiconductor device comprising:
a first semiconductor structure comprising a substrate, circuits on the substrate, and a lower interconnection structure electrically connected to the circuits; and
a second semiconductor structure comprising:
a plate layer on the first semiconductor structure;
gate electrodes and interlayer insulating layers alternately stacked on the plate layer in a first direction that is perpendicular to an upper surface of the plate layer;
channel structures passing through the gate electrodes and extending in the first direction; and
an upper capacitor structure comprising an upper gate electrode on the interlayer insulating layers and an upper contact structure extending through the upper gate electrode in the first direction,
wherein the upper contact structure comprises an upper contact plug and an upper contact insulating layer between a sidewall of the upper contact structure and the upper contact plug,
wherein the upper contact structure is electrically insulated from the channel structures,
wherein a central axis of the upper contact structure is offset from central axes of the channel structures, and
wherein the upper contact plug and the upper gate electrode are configured to have different potentials.

2. The semiconductor device of claim 1, further comprising a lower capacitor structure comprising the plate layer and a lower contact structure passing through the plate layer,
wherein the lower contact structure comprises a lower contact plug and a lower contact insulating layer between a sidewall of the lower contact structure and the lower contact plug, and
wherein the lower contact plug and the plate layer are configured to have different potentials.

3. The semiconductor device of claim 2, wherein the upper contact insulating layer comprises a plurality of the upper contact insulating layers having thicknesses different from each other, and
wherein the lower contact insulating layer comprises a plurality of lower contact insulating layers having thicknesses different from each other.

4. The semiconductor device of claim 2, wherein the upper contact plug is one of a plurality of upper contact plugs having widths different from each other, and
wherein the lower contact plug is one of a plurality of lower contact plugs having thicknesses different from each other.

5. The semiconductor device of claim 2, wherein the upper contact plug is electrically insulated from the lower contact plug, and
wherein the upper contact plug and the lower contact plug are configured to have different potentials.

6. The semiconductor device of claim 2, further comprising a peripheral contact plug electrically connecting the upper contact plug and the lower contact plug,
wherein the upper gate electrode and the plate layer are configured to have different potentials.

7. The semiconductor device of claim 6, further comprising an upper interconnection structure on the upper gate electrode and electrically connected to the upper contact plug,
wherein the upper interconnection structure, the upper contact plug, the peripheral contact plug, and the lower contact plug are configured to have a common potential.

8. The semiconductor device of claim 6, further comprising a second lower interconnection structure below the plate layer and electrically connected to the lower contact plug,
wherein the second lower interconnection structure, the lower contact plug, the peripheral contact plug, and the upper contact plug are configured to have a common potential.

9. The semiconductor device of claim 1, further comprising a lower capacitor structure comprising a peripheral contact plug spaced apart from the gate electrodes and the interlayer insulating layers and passing through the plate layer from the upper contact structure, and a peripheral contact insulating layer passing through the plate layer and surrounding the peripheral contact plug.

10. The semiconductor device of claim 1, further comprising:
a through-via structure passing through the gate electrodes and the interlayer insulating layers, electrically connected to the upper contact plug, and insulated from the gate electrodes; and
an intermediate capacitor structure comprising the through-via structure and the gate electrodes,
wherein the through-via structure comprises a through-via plug and a through-via insulating layer between a sidewall of the through-via structure and the through-via plug, and
wherein the through-via plug and the gate electrodes are configured to have different potentials.

11. The semiconductor device of claim 1, wherein a cross-section of the upper contact structure in a horizontal direction parallel to the upper surface of the plate layer, has a circular shape or a polygonal shape.

12. The semiconductor device of claim 1, wherein the upper gate electrode comprises a first upper gate electrode and a second upper gate electrode configured to have different potentials,
wherein the upper contact structure comprises a first upper contact structure in the first upper gate electrode and a second upper contact structure in the second upper gate electrode,
wherein the first upper contact structure comprises a first upper contact plug and a first upper contact insulating layer between a sidewall of the first upper contact structure and the first upper contact plug,
wherein the second upper contact structure comprises a second upper contact plug and a second upper contact insulating layer between a sidewall of the second upper contact structure and the second upper contact plug,
wherein the first upper contact plug and the first upper gate electrode are configured to have different potentials, and
wherein the second upper contact plug and the second upper gate electrode are configured to have different potentials.

13. The semiconductor device of claim 12, further comprising:
a first upper capacitor structure comprising the first upper gate electrode and the first upper contact structure;
a second upper capacitor structure comprising the second upper gate electrode and the second upper contact structure;
an external insulating layer between the first upper gate electrode and the second upper gate electrode; and
an external capacitor structure comprising the first upper gate electrode, the second upper gate electrode, and the external insulating layer.

14. A semiconductor device comprising:
a first semiconductor structure comprising a substrate, circuits on the substrate, and a lower interconnection structure electrically connected to the circuits; and
a second semiconductor structure on the first semiconductor structure, and comprising a first region, a second region adjacent to the first region, and a third region disposed outside the first region and the second region, the first region comprising cell blocks and dummy blocks arranged in a direction parallel to an upper surface of the substrate,
wherein the second semiconductor structure further comprises:
a plate layer on the first semiconductor structure;
gate electrodes and interlayer insulating layers alternately stacked on the plate layer in a first direction that is perpendicular to an upper surface of the plate layer;
an upper gate electrode on the interlayer insulating layers; and
an upper contact structure passing through the upper gate electrode,
wherein the upper contact structure comprises an upper contact plug and an upper contact insulating layer between a sidewall of the upper contact structure and the upper contact plug,
wherein the upper contact plug is configured to have a potential different from a potential of the upper gate electrode, and
wherein the second semiconductor structure further comprises an upper capacitor structure comprising the upper gate electrode, the upper contact insulating layer, and the upper contact plug in at least one region of the first to third regions.

15. The semiconductor device of claim 14, wherein the first region is a memory cell array,
wherein the second region is a connection region, and
wherein the third region is an external region.

16. The semiconductor device of claim 14, wherein the second semiconductor structure further comprises a lower capacitor structure comprising the plate layer and a lower contact structure passing through the plate layer, in at least one region of the first to third regions,
wherein the lower contact structure comprises a lower contact plug and a lower contact insulating layer between a sidewall of the lower contact structure and the lower contact plug, and
wherein the lower contact plug and the plate layer are configured to have different potentials.

17. The semiconductor device of claim 14, further comprising channel structures passing through the gate electrodes and extending in the first direction,
wherein in the dummy blocks, the upper contact structure is electrically insulated from the channel structures, a central axis of the upper contact structure is offset from central axes of the channel structures, and
wherein the upper capacitor structure is included in the dummy blocks.

18. The semiconductor device of claim 14, in the second region, further comprising:
a gate contact plug passing through the gate electrodes and the interlayer insulating layers and electrically connected to the upper contact plug and the gate electrodes, respectively;
gate contact insulating layers surrounding the gate contact plug; and
an intermediate capacitor structure comprising the gate contact plug, the gate contact insulating layers, and the gate electrodes,
wherein the gate contact plug and the gate electrodes are configured to have different potentials, and
wherein the gate electrodes extend to have different lengths from the first region to the second region, and have a stepped structure.

19. A data storage system comprising:
a semiconductor storage device; and
a controller,
wherein the semiconductor storage device comprises:
a first semiconductor structure comprising a substrate, circuits on the substrate, and a lower interconnection structure electrically connected to the circuits; and
a second semiconductor structure comprising:
a plate layer on the first semiconductor structure;
gate electrodes and interlayer insulating layers alternately stacked on the plate layer in a first direction that is perpendicular to an upper surface of the plate layer;
channel structures passing through the gate electrodes and extending in the first direction; and
an upper capacitor structure comprising an upper gate electrode on the interlayer insulating layers and an upper contact structure extending through the upper gate electrode in the first direction, and comprising an input/output pad electrically connected to the circuits,
wherein the upper contact structure comprises an upper contact plug and an upper contact insulating layer between a sidewall of the upper contact structure and the upper contact plug,
wherein the upper contact structure is electrically insulated from the channel structures,
wherein a central axis of the upper contact structure is offset from central axes of the channel structures,
wherein the upper contact plug and the upper gate electrode are configured to have different potentials, and
wherein the controller is electrically connected to the semiconductor storage device through the input/output pad and is configured to control the semiconductor storage device.

20. The data storage system of claim 19, further comprising:
a lower contact structure passing through the plate layer; and
a lower capacitor structure comprising the plate layer and the lower contact structure,
wherein the lower contact structure comprises a lower contact plug and a lower contact insulating layer between a sidewall of the lower contact structure and the lower contact plug,
wherein the lower contact plug and the plate layer have different potentials, and
wherein the plate layer and the upper gate electrode have different potentials.
